(19) United States
(12) Patent Application Publication
(10) Pub. No.: US 2024/0427068 A1
(43) Pub. Date: Dec. 26, 2024

(54) OPTICAL FILTER

(71) Applicant: AGC Inc., Tokyo (JP)

(72) Inventors: Kazuhiko SHIONO, Fukushima (JP); Kiyokazu ENDO, Fukushima (JP); Takashi NAGATA, Shizuoka (JP)

(73) Assignee: AGC Inc., Tokyo (JP)

(21) Appl. No.: 18/815,960

(22) Filed: Aug. 27, 2024

Related U.S. Application Data
(63) Continuation of application No. PCT/JP2023/006324, filed on Feb. 21, 2023.

(30) Foreign Application Priority Data
Mar. 2, 2022 (JP) 2022-032184

(51) Int. Cl. G02B 5/22; H01L 27/146

(52) U.S. Cl. CPC G02B 5/226; G02B 5/223; H01L 27/1462

(57) ABSTRACT

An optical filter includes: a substrate; a dielectric multilayer film (I) laid on or above one main surface of the substrate; and a dielectric multilayer film (II) laid on or above the other main surface of the substrate, in which the substrate includes a near-infrared ray absorbing glass and a resin film, the resin film includes a resin and a dye (NIR1), and the optical filter satisfies specific spectral characteristics.

### CROSS-REFERENCE TO RELATED APPLICATIONS

This is a bypass continuation of International Patent Application No. PCT/JP2023/006324, filed on Feb. 21, 2023, which claims priority to Japanese Patent Application No. 2022-032184, filed on Mar. 2, 2022. The contents of these applications are hereby incorporated by reference in their entireties.

### TECHNICAL FIELD

The present invention relates to an optical filter that transmits visible light and shields near-infrared light.

### BACKGROUND ART

In an imaging device including a solid state image sensor, in order to satisfactorily reproduce a color tone and obtain a clear image, an optical filter that transmits light in a visible region (hereinafter, also referred to as “visible light”) and shields light in a near-infrared wavelength region (hereinafter, also referred to as “near-infrared light”) is used.

Examples of such an optical filter include various types such as a reflection type filter in which dielectric thin films having different refractive indices are alternately laid (dielectric multilayer film) on one surface or both surfaces of a transparent substrate, and light desired to be shielded is reflected using interference of light.

Patent Literatures 1 and 2 disclose an optical filter including a dielectric multilayer film and an absorbing layer containing a dye.

### CITATION LIST

### Patent Literature

Patent Literature 1: WO2020/050177
Patent Literature 2: WO2020/004641

### SUMMARY OF INVENTION

Most of the light transmitted through the optical filter enters a sensor, but some of the light is reflected by the sensor surface, then further reflected on the dielectric multilayer film on a back surface side of the optical filter, and re-enters the sensor, which can result in a phenomenon in which light is generated outside an originally assumed optical path, that is, so-called stray light. The stray light caused by repeated reflection between such an optical filter and the sensor may cause flare or ghosting in the solid state image sensor, resulting in degradation of image quality. With image quality enhancement of camera modules in recent years, an optical filter that is less susceptible to flare and ghosting is required. In particular, since a sensor sensitivity is high in a wavelength region of 700 nm to 800 nm, it is desirable to prevent flare and ghosting in such a wavelength region.

An optical film thickness of the dielectric multilayer film changes depending on an incident angle of light, reflection characteristics can change, and thus flare and ghosting are more likely to occur as the incident angle increases. In particular, with a reduction in height of camera modules in recent years, use under a condition of a high incident angle is assumed, and therefore an optical filter that is hardly affected by an incident angle is required.

An object of the present invention is to provide an optical filter in which transmissivity in a visible light region and a shielding property in a near-infrared light region are excellent and flare and ghosting can be prevented even at a high incident angle.

The present invention provides an optical filter having the following configuration.

[1] An optical filter including:
a substrate;
a dielectric multilayer film (I) laid on or above one main surface of the substrate as an outermost layer; and
a dielectric multilayer film (II) laid on or above the other main surface of the substrate as an outermost layer, in which
the substrate includes a near-infrared ray absorbing glass and a resin film, the resin film being laid on or above at least one main surface of the near-infrared ray absorbing glass, the resin film includes a resin and a dye (NIR1) having a maximum absorption wavelength at 680 nm to 870 nm in the resin, and
the optical filter satisfies all of the following spectral characteristics (i-1) to (i-8):
(i-1) an average transmittance T_{440-600(0deg)AVE} at a wavelength of 440 nm to 600 nm in a spectral transmittance curve at an incident angle of 0 degrees is 86% or more,
(i-2) an absolute value of a difference between a wavelength IR50_{(40deg)T} at which a transmittance is 50% in a wavelength range of 550 nm to 750 nm in the spectral transmittance curve at the incident angle of 0 degrees and a wavelength IR50_{(40deg)T} at which a transmittance is 50% in the wavelength range of 550 nm to 750 nm in a spectral transmittance curve at an incident angle of 40 degrees is 6 nm or less,
(i-3) an average transmittance T_{700-800(0deg)AVE} at a wavelength of 700 nm to 800 nm in the spectral transmittance curve at the incident angle of 0 degrees is 1% or less,
(i-4) an average transmittance T_{800-1200(0deg)AVE} at a wavelength of 800 nm to 1200 nm in the spectral transmittance curve at the incident angle of 0 degrees is 3% or less,
(i-5) when a side of the dielectric multilayer film (I) is set as an incident direction, an average reflectance RI_{440-600(5deg)AVE} at a wavelength of 440 nm to 600 nm in a spectral reflectance curve at an incident angle of 5 degrees is 4% or less,
(i-6) when the side of the dielectric multilayer film (I) is set as the incident direction, an average reflectance RI_{800-1200(5deg)AVE} at a wavelength of 800 nm to 1200 nm in the spectral reflectance curve at the incident angle of 5 degrees is 95% or more,
(i-7) when a side of the dielectric multilayer film (II) is set as the incident direction, an average reflectance RII_{700-800(40deg)AVE} at a wavelength of 700 nm to 800 nm in a spectral reflectance curve at an incident angle of 40 degrees is 5.5% or less, and
(i-8) when the side of the dielectric multilayer film (II) is set as the incident direction, an average reflectance RII_{800-1200(40deg)AVE} at a wavelength of 800 nm to 1200 nm in the spectral reflectance curve at the incident angle of 40 degrees is 10% or more.

According to the present invention, an optical filter in which transmissivity in a visible light region and a shielding property in a near-infrared light region are excellent and flare and ghosting can be prevented even at a high incident angle can be provided.

### BRIEF DESCRIPTION OF DRAWINGS

FIG. 1 is a cross-sectional view schematically illustrating an example of an optical filter according to one embodiment.

FIG. 2 is a cross-sectional view schematically illustrating another example of the optical filter according to one embodiment.

FIG. 3 is a diagram illustrating a mechanism of occurrence of repeated reflection between a sensor and an optical filter.

FIG. 4 is a diagram illustrating spectral transmittance curves of a resin film in Example 1-1 and a resin film in Example 1-2.

FIG. 5 is a diagram illustrating spectral reflectance curves of a dielectric multilayer film (II) in Example 3-3 and a dielectric multilayer film (II) in Example 3-4.

FIG. 6 is a diagram illustrating spectral transmittance curves of an optical filter in Example 4-1 at incident angles of 0 degrees and 40 degrees and a spectral reflectance curve at an incident angle of 5 degrees with an incident direction on a side of a dielectric multilayer film (I).

FIG. 7 is a diagram illustrating a spectral reflectance curve of the optical filter in Example 4-1 at the incident angle of 40 degrees with the incident direction on a side of a dielectric multilayer film (II).

FIG. 8 is a diagram illustrating spectral transmittance curves of an optical filter in Example 4-2 at incident angles of 0 degrees and 40 degrees and a spectral reflectance curve at an incident angle of 5 degrees with the incident direction on a side of a dielectric multilayer film (I).

FIG. 9 is a diagram illustrating a spectral reflectance curve of the optical filter in Example 4-2 at the incident angle of 40 degrees with the incident direction on a side of a dielectric multilayer film (II).

### DESCRIPTION OF EMBODIMENTS

Hereinafter, embodiments of the present invention will be described.

In the present description, a near-infrared ray absorbing dye may be abbreviated as an “NIR dye”, and an ultraviolet ray absorbing dye may be abbreviated as a “UV dye”.

In the present description, a compound represented by a formula (I) is referred to as a compound (I). The same applies to compounds represented by other formulae. A dye composed of the compound (I) is also referred to as a dye (I), and the same applies to other dyes. In addition, a group represented by the formula (I) is also referred to as a group (I), and the same applies to groups represented by other formulae.

In the present description, an internal transmittance is a transmittance obtained by subtracting an influence of interface reflection from a measured transmittance, which is represented by a formula {measured transmittance (incident angle 0 degrees)/(100−reflectance (incident angle 5 degrees))}×100.

In the present description, a transmittance of a substrate and a spectrum of a transmittance of a resin film including a case where a dye is contained in a resin are all “internal transmittance” even when described as a “transmittance”. On the other hand, a transmittance of a dielectric multilayer film and a transmittance of an optical filter including the dielectric multilayer film are a measured transmittance.

In the present description, a transmittance of, for example, 90% or more in a specific wavelength region means that the transmittance does not fall below 90% in the entire wavelength region, that is, a minimum transmittance is 90% or more in the wavelength region. Similarly, a transmittance of, for example, 1% or less in a specific wavelength region means that the transmittance does not exceed 1% in the entire wavelength region, that is, a maximum transmittance is 1% or less in the wavelength region. The same applies to the internal transmittance. An average transmittance and an average internal transmittance in a specific wavelength region are an arithmetic mean of a transmittance and an internal transmittance per 1 nm in the wavelength region.

Spectral characteristics can be measured by using an ultraviolet-visible spectrophotometer.

In the present description, the symbol “-” or the word “to” that is used to express a numerical range includes the numerical values before and after the symbol or the word as the upper limit and the lower limit of the range, respectively.

### <Optical Filter>

An optical filter (hereinafter, also referred to as “the filter”) according to one embodiment of the present invention includes a substrate, a dielectric multilayer film 1 laid on or above one major surface of the substrate as an outermost layer, and a dielectric multilayer film 2 laid on or above the other major surface of the substrate as an outermost layer.

Here, the substrate includes a near-infrared ray absorbing glass and a resin film laid on or above at least one main surface of the near-infrared ray absorbing glass. Further, the resin film includes a resin and a dye (NIR1) having a maximum absorption wavelength in the resin at 680 nm to 870 nm.

Reflection characteristics of the dielectric multilayer film and absorption characteristics of the substrate including the near-infrared ray absorbing glass and the near-infrared ray absorbing dye allow the optical filter as a whole to implement excellent transmissivity in a visible light region and excellent shielding property in a near-infrared light region.

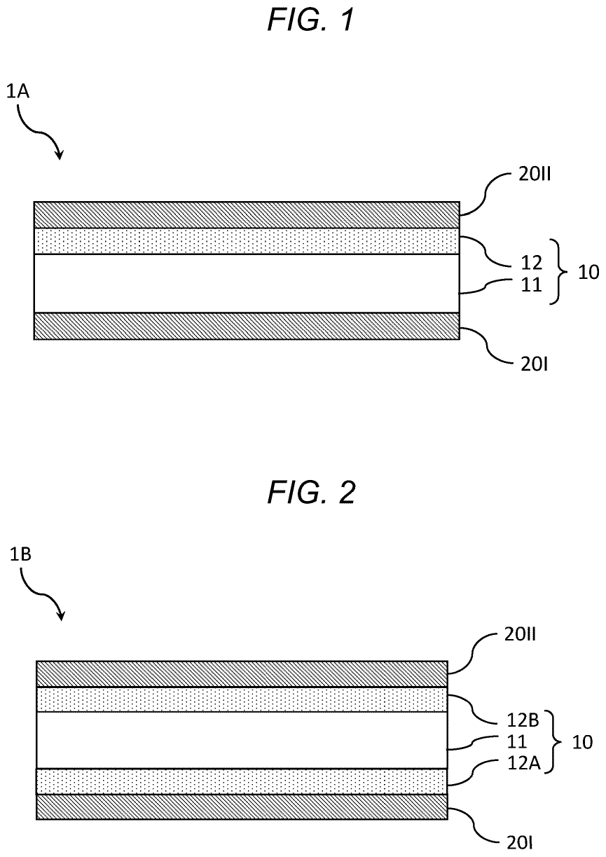

An example of a configuration of the present filter will be described with reference to the drawings. FIGS. 1 and 2 are cross-sectional views schematically illustrating examples of the optical filter according to one embodiment.

An optical filter 1A illustrated in FIG. 1 is an example in which a dielectric multilayer film 20I is provided on one main surface side of a substrate 10 including a near-infrared ray absorbing glass 11 and a resin film 12, that is, on the near-infrared ray absorbing glass 11 in FIG. 1, and a dielectric multilayer film 20II is provided on the other main surface side, that is, on the resin film 12 in FIG. 1. Noted that “including a specific layer on or above a main surface of a substrate” is not limited to a case where the layer is provided in contact with the main surface of the substrate, and includes a case where another functional layer is provided between the substrate and the layer.

An optical filter 1B illustrated in FIG. 2 is an example in which the substrate 10 includes resin films 12A and 12B on both main surfaces of the near-infrared ray absorbing glass 11, and the dielectric multilayer films 20I and 20II on both main surfaces of the substrate 10.

The optical filter of the present invention satisfies all of the following spectral characteristics (i-1) to (i-8):
(i-1) an average transmittance T_{440-600(0deg)AVE} at a wavelength of 440 nm to 600 nm in a spectral transmittance curve at an incident angle of 0 degrees is 86% or more,
(i-2) an absolute value of a difference between a wavelength IR50_{(40deg)T} at which a transmittance is 50% in a wavelength range of 550 nm to 750 nm in the spectral transmittance curve at the incident angle of 0 degrees and a wavelength IR50_{(40deg)T} at which a transmittance is 50% in the wavelength range of 550 nm to 750 nm in a spectral transmittance curve at an incident angle of 40 degrees is 6 nm or less,
(i-3) an average transmittance T_{700-800(0deg)AVE} at a wavelength of 700 nm to 800 nm in the spectral transmittance curve at the incident angle of 0 degrees is 1% or less,
(i-4) an average transmittance T_{800-1200(0deg)AVE} at a wavelength of 800 nm to 1200 nm in the spectral transmittance curve at the incident angle of 0 degrees is 3% or less,
(i-5) when a side of the dielectric multilayer film (I) is set as an incident direction, an average reflectance RI_{440-600(5deg)AVE} at a wavelength of 440 nm to 600 nm in a spectral reflectance curve at an incident angle of 5 degrees is 4% or less,
(i-6) when the side of the dielectric multilayer film (I) is set as the incident direction, an average reflectance RI_{800-1200(5deg)AVE} at a wavelength of 800 nm to 1200 nm in the spectral reflectance curve at the incident angle of 5 degrees is 95% or more,
(i-7) when a side of the dielectric multilayer film (II) is set as the incident direction, an average reflectance RI_{700-800(40deg)AVE} at a wavelength of 700 nm to 800 nm in a spectral reflectance curve at an incident angle of 40 degrees is 5.5% or less, and
(i-8) when the side of the dielectric multilayer film (II) is set as the incident direction, an average reflectance RII_{800-1200(40deg)AVE} at a wavelength of 800 nm to 1200 nm in the spectral reflectance curve at the incident angle of 40 degrees is 10% or more.

The optical filter of the present invention reflects near-infrared light on one main surface side of the optical filter, that is, on the side of the dielectric multilayer film (I), as shown in the characteristic (i-6), while preventing reflection of near-infrared light on the other main surface side, that is, on the side of the dielectric multilayer film (II), as shown in the characteristic (i-7).

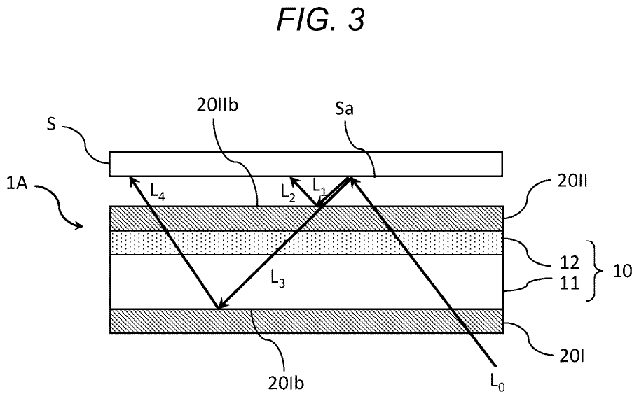

As illustrated in FIG. 3, an incident light L₀ is transmitted through the optical filter 1A, and a part of the incident light L₀ is reflected on one main surface Sa of a sensor S (a reflection light L₁). The reflection light L₁ is reflected on a back surface of the optical filter, that is, on a main surface 20IIb of the dielectric multilayer film 20II (a reflection light L₂), and the reflection light L₂ re-enters the sensor S, which can cause flare or ghosting. When the optical filter is mounted such that the main surface side for preventing reflection of the near-infrared light, that is, the side of the dielectric multilayer film (II) faces the sensor, back surface reflection of the optical filter which causes flare or ghosting can be prevented.

The optical filter of the present invention is also excellent in transmissivity in a visible light region and shielding property in a near-infrared light region even at a high incident angle, as shown by the characteristics (i-1) to (i-4).

Hereinafter, each characteristic will be described in detail.

Satisfying the spectral characteristic (i-1) means that the transmissivity in the visible light region is excellent.

The average transmittance T_{440-600(0deg)AVE} is preferably 88% or more, and more preferably 90% or more.

In order to satisfy the spectral characteristic (i-1), for example, a dielectric multilayer film having a small visible light reflectance may be used.

Satisfying the spectral characteristic (i-2) means that a spectral transmittance curve in a region of 550 nm to 750 nm is unlikely to shift even at a high incident angle.

The absolute value in the spectral characteristic (i-2) is preferably 3 nm to 5 nm, and more preferably 3 nm to 4 nm.

In order to satisfy the spectral characteristic (i-2), for example, the absorption characteristics of the NIR dye can be used to shield light in a wavelength region of 600 nm to 700 nm. When utilizing the absorption characteristics of the dye, the transmittance in the visible light region of 440 nm to 600 nm is also likely to decrease due to absorption by the dye. Therefore, it is preferable to select a dye according to a desired light-shielding band from among dyes having a squarylium structure to be described below.

Satisfying the spectral characteristic (i-3) means that a light-shielding property in the near-infrared region of 700 nm to 800 nm is excellent.

The average transmittance T_{700-800(0deg)AVE} is preferably 0.3% or less, and more preferably 0.15% or less.

In order to satisfy the spectral characteristic (i-3), for example, a dye capable of absorbing light of 700 nm to 800 nm can be used.

Satisfying the spectral characteristic (i-4) means that the light-shielding property in the near-infrared region of 800 nm to 1200 nm is excellent.

The average transmittance T_{800-1200(0deg)AVE} is preferably 1% or less, and more preferably 0.5% or less.

In order to satisfy the spectral characteristic (i-4), for example, a near-infrared reflectance of one of the dielectric multilayer films may be increased, or a near-infrared ray absorbing glass may be used.

Satisfying the spectral characteristic (i-5) means that the transmissivity in the visible light region is excellent.

The average reflectance RI_{440-600(5deg)AVE} is preferably 3% or less, and more preferably 1.5% or less.

In order to satisfy the spectral characteristic (i-5), for example, the visible light reflectance of the dielectric multilayer film (I) may be designed to be small.

Satisfying the spectral characteristic (i-6) means that the light-shielding property in the near-infrared region of 800 nm to 1200 nm is excellent.

The average reflectance RI_{800-1200(5deg)AVE} is preferably 97% or more, and more preferably 98% or more.

In order to satisfy the spectral characteristic (i-6), for example, the near-infrared light reflectance of the dielectric multilayer film (I) may be designed to be large.

Satisfying the spectral characteristic (i-7) means that the reflectance in the near-infrared region of 700 nm to 800 nm is small even at a high incident angle.

The average reflectance RII_{700-800(40deg)AVE} is preferably 3% or less, and more preferably 2% or less.

In order to satisfy the spectral characteristic (i-7), for example, the reflectance of the dielectric multilayer film (II) at 700 nm to 800 nm may be designed to be small.

The spectral characteristic (i-8) refers to a range in which reflection in the near-infrared region of 800 nm to 1200 nm is permitted at a high incident angle.

The average reflectance RII_{800-1200(40deg)AVE} is preferably 20% or more, and more preferably 30% or more.

In order to satisfy the spectral characteristic (i-8), for example, the reflectance of the dielectric multilayer film (II) at 800 nm to 1200 nm may be designed to be large.

The optical filter of the present invention preferably further satisfies the following spectral characteristics (i-9) to (i-10): (i-9) when the side of the dielectric multilayer film (II) is set as the incident direction, an average reflectance RI_{700-800(50deg)AVE} at a wavelength of 700 nm to 800 nm in a spectral reflectance curve at an incident angle of 50 degrees is 8% or less, and (i-10) when the side of the dielectric multilayer film (II) is set as the incident direction, an average reflectance RII_{800-1200(50deg)AVE} at a wavelength of 800 nm to 1200 nm in the spectral reflectance curve at the incident angle of 50 degrees is 10% or more.

Satisfying the spectral characteristic (i-9) means that the reflectance in the near-infrared region of 700 nm to 800 nm is small even at a higher incident angle.

The average reflectance RII_{700-800(50deg)AVE} is preferably 5% or less, and more preferably 4% or less.

The spectral characteristic (i-10) refers to a range in which reflection in the near-infrared region of 800 nm to 1200 nm is permitted at a higher incident angle.

The average reflectance RII_{800-1200(50deg)AVE} is preferably 20% or more, and more preferably 30% or more.

The optical filter of the present invention preferably further satisfies the following spectral characteristic (i-12):
(i-12) an absolute value of a difference between IR50_{(40deg)T} and IR50_{(5deg)R} is 85 nm or more, where the IR50_{(0deg)T} is a wavelength at which a transmittance is 50% in a wavelength range of 550 nm to 750 nm in the spectral transmittance curve at the incident angle of 0 degrees and the IR50_{(5deg)R} is a wavelength at which a reflectance is 50% in a wavelength range of 550 nm to 750 nm in the spectral reflectance curve at the incident angle of 5 degrees when the side of the dielectric multilayer film (I) is set as the incident direction.

The spectral characteristic (i-12) defines a relationship between the transmittance and the reflectance when light enters from the side of the dielectric multilayer film (I), and means that a wavelength position where the reflectance is 50% (IR50_{(5deg)R}) is sufficiently far away from a wavelength position where the transmittance is 50% (IR50_{(0deg)T}) on a long wavelength side.

As illustrated in FIG. 3, the incident light L₀ is transmitted through the optical filter 1A, and a part of the incident light L₀ is reflected on one main surface Sa of the sensor S (a reflection light L₃). The reflection light L₃ re-enters the optical filter 1A and is reflected on an inner surface 20Ib of the dielectric multilayer film 20I (a reflection light L₄). The reflection light L₄ re-enters the sensor S, which can also cause flare or ghosting, similar to the reflection light L₂.

By satisfying the spectral characteristics (i-12), internal reflection of the dielectric multilayer film 20I at a wavelength of 550 nm to 750 nm can be prevented, and flare and ghosting can be prevented.

Since the IR50_{(5deg)R} is sufficiently far away on the long wavelength side, the light-shielding property at 700 nm to 800 nm can be compensated by the absorption characteristics of the near-infrared ray absorbing dye rather than the reflection characteristics.

The IR50_{(0deg)T} is preferably in a range of 615 nm to 670 nm.

The IR50_{(5deg)R} is preferably in a range of 700 nm to 750 nm.

The absolute value of the difference between the IR50_{(0deg)T} and the IR50_{(5deg)R} is more preferably 85 nm or more.

### <Dielectric Multilayer Film>

In the present filter, the dielectric multilayer films are laid, as outermost layers, on or above both main surfaces of the substrate.

The dielectric multilayer film (I) is laid on or above one main surface of the substrate, and the dielectric multilayer film (II) is laid on or above the other main surface of the substrate.

The dielectric multilayer film (I) preferably satisfies all of the following spectral characteristics (v-I-1) to (v-I-4):
(v-I-1) an average reflectance RI_{440-600(5deg)AVE} at a wavelength of 440 nm to 600 nm in the spectral reflectance curve at the incident angle of 5 degrees is 10% or less,
(v-I-2) an average reflectance RI_{800-1200(5deg)AVE} at a wavelength of 800 nm to 1200 nm in the spectral reflectance curve at the incident angle of 5 degrees is 95% or more,
(v-I-3) an average reflectance RI_{440-600(40deg)AVE} at a wavelength of 440 nm to 600 nm in the spectral reflectance curve at the incident angle of 40 degrees is 11% or less, and (v-I-4) an average reflectance RI_{800-1200(40deg)AVE} at a wavelength of 800 nm to 1200 nm in the spectral reflectance curve at the incident angle of 40 degrees is 88% or more.

Satisfying the spectral characteristic (v-I-1) means that the transmissivity in the visible light region is excellent.

The average reflectance RI_{440-600(5deg)AVE} is preferably 8% or less, and more preferably 6% or less.

Satisfying the spectral characteristic (v-I-2) means that the reflection characteristics of near-infrared light of 800 nm to 1200 nm are excellent.

The average reflectance RI_{800-1200(5deg)AVE} is preferably 96% or more, and more preferably 98% or more.

Satisfying the spectral characteristic (v-I-3) means that the transmissivity in the visible light region is excellent even at a high incident angle.

The average reflectance RI_{440-600(40deg)AVE} is preferably 10% or less, and more preferably 9% or less.

Satisfying the spectral characteristic (v-I-4) means that the reflection characteristics of near-infrared light of 800 nm to 1200 nm are excellent even at a high incident angle.

The average reflectance RI_{800-1200(40deg)AVE} is preferably 89% or more, and more preferably 90% or more.

By designing the dielectric multilayer film (I) to satisfy the spectral characteristics (v-I-1) to (v-I-4), the optical filter is likely to satisfy the spectral characteristic (i-5) and the spectral characteristic (i-6).

The dielectric multilayer film (I) mainly functions as a reflection film that reflects near-infrared light as described above.

The dielectric multilayer film (II) preferably satisfies all of the following spectral characteristics (v-II-1) and (v-II-2):
(v-II-1) a maximum reflectance RII_{700-800(5deg)MAX} at a wavelength of 700 nm to 800 nm in a spectral reflectance curve at an incident angle of 5 degrees is 8% or less, and
(v-II-2) an average reflectance RII_{700-800(5deg)AVE} at the wavelength of 700 nm to 800 nm in the spectral reflectance curve at the incident angle of 5 degrees is 6% or less.

Satisfying the spectral characteristic (v-II-1) and the spectral characteristic (v-II-2) means that the reflectance at a wavelength of 700 nm to 800 nm is small. By designing the reflectance at the wavelength of 700 nm to 800 nm to be small in the dielectric multilayer film (II), the optical filter is likely to satisfy the spectral characteristic (i-7).

The maximum reflectance RII_{700-800(5deg)MAX} is preferably 7.5% or less, and more preferably 6% or less.

The average reflectance RII_{700-800(5deg)AVE} is preferably 5.5% or less, and more preferably 5% or less.

The dielectric multilayer film (II) preferably further satisfies the following spectral characteristic (v-II-5):
(v-II-5) an average reflectance RII_{800-1200(5deg)AVE} at a wavelength of 800 nm to 1200 nm in the spectral reflectance curve at the incident angle of 5 degrees is 20% or more.

Satisfying the spectral characteristic (v-II-5) means that the reflectance at a wavelength of 800 nm to 1200 nm is high.

The average reflectance RII_{800-1200(5deg)AVE} is preferably 27% or more, and more preferably 25% or more.

The dielectric multilayer film (II) preferably further satisfies the following spectral characteristic (v-II-6):
(v-II-6) an average reflectance RII_{440-600(5deg)AVE} at a wavelength of 440 nm to 600 nm in a spectral reflectance curve at an incident angle of 5 degrees is 6% or less.

Satisfying the spectral characteristic (v-II-6) means that the transmissivity in the visible light region is excellent.

The average reflectance RII_{440-600(5deg)AVE} is more preferably 5% or less.

The spectral characteristics of the dielectric multilayer film (I) and the dielectric multilayer film (II) can be obtained by measuring the reflectance of each of the dielectric multilayer films formed on or above a transparent glass substrate.

In the present filter, the dielectric multilayer film (I) is designed as a near-infrared light reflection layer (hereinafter, also referred to as an NIR reflection layer), and the dielectric multilayer film (II) is designed as a near-infrared light antireflection layer (hereinafter, also referred to as an NIR antireflection layer).

The NIR reflection layer and the NIR antireflection layer are formed of, for example, a dielectric multilayer film in which dielectric films having different refractive indices are alternately laid.

Examples of the dielectric film include a dielectric film having a low refractive index (low refractive index film) and a dielectric film having a high refractive index (high refractive index film), and the dielectric films are preferably alternately laid.

A refractive index of the high refractive index film is preferably 1.6 or more, and more preferably 2.2 to 2.5. Examples of a material of the high refractive index film include Ta₂O₅, TiO₂, and Nb₂O₅. Among them, TiO₂ is preferred from the viewpoint of reproducibility in film-formability and refractive index, stability, and the like.

The low refractive index film preferably has a refractive index of less than 1.6, and more preferably 1.4 or more and 1.5 or less. Examples of a material of the low refractive index film include SiO₂ and SiOₓN_{y}. SiO₂ is preferred from the viewpoint of reproducibility in film-formability, stability, economic efficiency, and the like.

In order to obtain the dielectric multilayer film in which such reflection characteristics are prevented as described above, several types of dielectric films having different spectral characteristics may be combined when transmitting and selecting a desired wavelength band.

In the NIR reflection layer, a total number of laid dielectric multilayer films is preferably 20 or more, more preferably 30 or more, and further preferably 40 or more, and is preferably 60 or less from the viewpoint of productivity and the viewpoint of reducing warpage of the substrate.

A film thickness of the NIR reflection layer is preferably 3 μm to 6 μm as a whole.

In the NIR antireflection layer, a total number of laid dielectric multilayer films is preferably 30 or less, more preferably 25 or less, and further preferably 20 or less, and is preferably 4 or more.

A film thickness of the NIR antireflection layer is preferably 0.1 μm to 2 μm as a whole.

For formation of the dielectric multilayer film, for example, a vacuum film formation process such as a CVD method, a sputtering method, or a vacuum deposition method, a wet film formation process such as a spraying method or a dipping method, or the like can be used.

The dielectric multilayer film may provide predetermined optical characteristics with one layer (one group of dielectric multilayer films) or may provide predetermined optical characteristics with two or more layers. When two or more dielectric multilayer films are provided, the respective dielectric multilayer films may have the same structure or different structures.

The dielectric multilayer film (I) and the dielectric multilayer film (II) may be laid on or above either main surface of the substrate, and generally, the dielectric multilayer film (I) is preferably laid on a near-infrared ray absorbing glass side, and the dielectric multilayer film (II) is preferably laid on a resin film side. The dielectric multilayer film (II) functioning as an antireflection layer generally has layers and thickness smaller than those of the dielectric multilayer film (I) functioning as a reflection layer, and therefore a stress applied to the resin film can be reduced. When the stress applied to the resin film is small, wrinkles are less likely to occur in the resin film even when the resin is softened under a high temperature and high humidity, and thus reliability can be improved.

When the optical filter is mounted on an imaging device, the dielectric multilayer film (I) which is an NIR reflection layer is disposed on a lens side, and the dielectric multilayer film (II) which is an NIR antireflection layer is disposed on a sensor side. With such a configuration, repeated reflection between the sensor and the optical filter can be reduced, and the occurrence of flare and ghosting can be prevented.

### <Substrate>

In the optical filter of the present invention, the substrate includes the near-infrared ray absorbing glass and the resin film. The resin film includes the resin and the dye (NIR1) having a maximum absorption wavelength in the resin at 680 nm to 870 nm, and is laid on or above at least one main surface of the near-infrared ray absorbing glass. As described above, the substrate has both an absorption ability of the near-infrared ray absorbing glass and an absorption ability of the resin film including the near-infrared ray absorbing dye (NIR1).

### <Near-Infrared Ray Absorbing Glass>

The near-infrared ray absorbing glass preferably satisfies all of the following spectral characteristics (iii-1) to (iii-3):
(iii-1) an average internal transmittance T_{400-600AVE} at a wavelength of 400 nm to 600 nm is 90% or more,
(iii-2) an average internal transmittance T_{700-800AVE} at a wavelength of 700 nm to 800 nm is 40% or less, and
(iii-3) an average internal transmittance T_{800-1200AVE} at a wavelength of 800 nm to 1200 nm is 40% or less.

Satisfying the spectral characteristic (iii-1) means that the transmissivity in a visible light region of 400 nm to 600 nm is excellent.

The average internal transmittance T_{400-600AVE} is more preferably 92% or more, and further preferably 95% or more.

Satisfying the spectral characteristic (iii-2) means that a light-shielding property in a near-infrared region of 700 nm to 800 nm is excellent.

The average internal transmittance T_{700-800AVE} is more preferably 30% or less, and further preferably 25% or less.

Satisfying the spectral characteristic (iii-3) means that a light-shielding property in a near-infrared region of 800 nm to 1200 nm is excellent.

The average internal transmittance T_{800-1200AVE} is more preferably 30% or less, and further preferably 25% or less.

The near-infrared ray absorbing glass is not limited as long as it is a glass capable of obtaining the above-described spectral characteristics, and examples thereof include an absorption type glass containing a copper ion, such as a fluorophosphate glass or a phosphate glass. The “phosphate glass” also includes a silicophosphate glass in which a part of a skeleton of glass is formed of SiO₂.

As the near-infrared ray absorbing glass, a chemically strengthened glass may be used which is obtained by exchanging alkali metal ions (for example, Li ions and Na ions) having a small ionic radius present on a main surface of a glass plate with alkali ions having a larger ionic radius (for example, Na ions or K ions with respect to Li ions and K ions with respect to Na ions) by ion exchange at a temperature equal to or lower than a glass transition point.

The thickness of the near-infrared ray absorbing glass is preferably 0.5 mm or less, more preferably 0.3 mm or less from the viewpoint of reduction in height of camera modules, and is preferably 0.15 mm or more from the viewpoint of element strength.

### <Resin Film>

The resin film preferably satisfies all of the following spectral characteristics (iv-1) to (iv-3):
(iv-1) an average internal transmittance T_{440-600AVE} at a wavelength of 440 nm to 600 nm is 90% or more,
(iv-2) an average internal transmittance T_{700-800AVE} at a wavelength of 700 nm to 800 nm is 50% or less, and
(iv-3) IR50_{(L)}−IR50_{(S)}≥100 nm, where the IR50_{(S)} is a shortest wavelength and the IR50_{(L)} is a longest wavelength at which an internal transmittance is 50% in a spectral transmittance curve at a wavelength of 600 nm to 800 nm.

Satisfying the spectral characteristic (iv-1) means that the transmissivity in the visible light region of 440 nm to 600 nm is excellent.

The average internal transmittance T_{440-600AVE} is more preferably 93% or more, and further preferably 95% or more.

In order to satisfy the spectral characteristic (iv-1), for example, an NIR dye having a small absorption characteristic in the visible light region may be used, and a content of the NIR dye may be reduced.

Satisfying the spectral characteristic (iv-2) means that a light-shielding property for near-infrared light having a wavelength of 700 nm to 800 nm is excellent.

The average internal transmittance T_{700-800AVE} is more preferably 45% or less, and further preferably 20% or less.

In order to satisfy the spectral characteristic (iv-2), for example, an NIR dye having a maximum absorption wavelength in a wavelength range of 700 nm to 800 nm can be used.

Satisfying the spectral characteristic (iv-3) means that light in a near-infrared light region of a wavelength of 600 nm to 800 nm can be broadly shielded.

IR50_{(L)}−IR50_{(S)} is more preferably 105 nm or more, and further preferably 110 nm or more.

The IR50_{(L)} is preferably 720 nm to 810 nm, and the IR50_{(S)} is preferably 620 nm to 670 nm.

In order to satisfy the spectral characteristic (iv-3), for example, two or more kinds of NIR dyes may be used.

The resin film in the present invention includes a dye (NIR1) having a maximum absorption wavelength at 680 nm to 870 nm, and thus is excellent in light-shielding property for near-infrared light of 700 nm to 800 nm, as shown in the above-described characteristic (iv-2), and is particularly excellent in a wide light-shielding property in the near-infrared light region of 600 nm to 800 nm, as shown in the above-described characteristic (iv-3). Accordingly, the reflection characteristics of the dielectric multilayer film (I) and the dielectric multilayer film (II) at 700 nm to 800 nm are prevented in order to reduce flare and ghosting, this can be compensated by the absorption characteristic of the NIR dye, and the optical filter as a whole can achieve both prevention of the flare and ghosting and shielding property for near-infrared light.

The dye (NIR1) has a maximum absorption wavelength in the resin at 680 nm to 870 nm, and preferably at 700 nm to 730 nm. Here, the resin refers to a resin constituting the resin film.

The NIR dye may be constituted of one kind of compound or may include two or more kinds of compounds.

Here, the resin film in the present invention preferably further includes, in addition to the dye (NIR1), another near-infrared ray absorbing dye having a different maximum absorption wavelength. Accordingly, a wide light-shielding property in the near-infrared light region in the vicinity of 700 nm can be obtained, and the resin film is likely to satisfy the characteristic (iv-3). The another near-infrared ray absorbing dye is preferably a dye (NIR2) having a maximum absorption wavelength longer than that of the dye (NIR1) by 30 nm to 130 nm in the resin. The maximum absorption wavelength of the dye (NIR2) is preferably 740 nm to 870 nm.

The dye (NIR1) is preferably a squarylium compound and a phthalocyanine compound from the viewpoint of a region of the maximum absorption wavelength, transmissivity in the visible light region, a solubility in a resin, and durability. A squarylium compound is particularly preferred. The maximum absorption wavelength of the squarylium compound as the dye (NIR1) is preferably 680 nm to 740 nm.

The dye (NIR2) is preferably a squarylium compound and a cyanine compound from the viewpoint of the region of the maximum absorption wavelength, the transmissivity in the visible light region, the solubility in a resin, and the durability. The maximum absorption wavelength of the squarylium compound as the dye (NIR2) is preferably 740 nm to 770 nm. The maximum absorption wavelength of the cyanine compound as the dye (NIR2) is preferably 740 nm to 860 nm.

### <NIR1: Squarylium Compound>

When two or more identical symbols are present in the squarylium compound, the symbols may be the same as or different from each other. The same applies to the cyanine compound.

### <Squarylium Compound (I)>

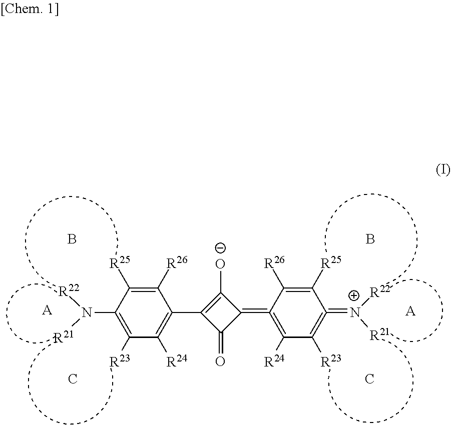

Here, symbols in the above-described formula are as follows.

R²⁴ and R²⁶ each independently represent a hydrogen atom, a halogen atom, a hydroxyl group, an alkyl group or an alkoxy group having 1 to 20 carbon atoms, an acyloxy group having 1 to 10 carbon atoms, an aryl group having 6 to 11 carbon atoms, an alkaryl group having 7 to 18 carbon atoms which may have a substituent and may have an oxygen atom between carbon atoms, —NR²⁷R²⁸ (R²⁷ and R²⁸ each independently represent a hydrogen atom, an alkyl group having 1 to 20 carbon atoms, —C(═O)—R²⁹ (R²⁹ is a hydrocarbon group having 1 to 25 carbon atoms which may have a hydrogen atom, a halogen atom, a hydroxyl group, or a substituent, and may have an unsaturated bond, an oxygen atom, or a saturated or unsaturated ring structure between carbon atoms), —NHR³⁰ or —SO₂—R³⁰ (R³⁰ is a hydrocarbon group having 1 to 25 carbon atoms in which one or more hydrogen atoms may be substituted with a halogen atom, a hydroxyl group, a carboxy group, a sulfo group, or a cyano group, and may have an unsaturated bond, an oxygen atom, or a saturated or unsaturated ring structure between carbon atoms)), or a group represented by the following formula (S) (R⁴¹ and R⁴² each independently represent a hydrogen atom, a halogen atom, or an alkyl group or an alkoxy group having 1 to 10 carbon atoms. K is 2 or 3).

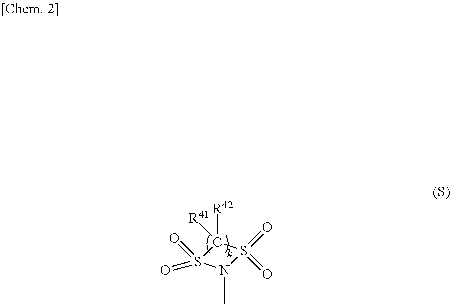

R²¹ and R²², R²² and R²⁵, and R²¹ and R²³ may each be linked to each other to form a 5 or 6-membered heterocycle A, heterocycle B, and heterocycle C, respectively, together with nitrogen atoms.

R²¹ and R²² in the case where the heterocycle A is formed represent, as a divalent group -Q- to which R²¹ and R²² are bonded, an alkylene group or an alkyleneoxy group in which a hydrogen atom may be substituted with an alkyl group having 1 to 6 carbon atoms, an aryl group having 6 to 10 carbon atoms, or an acyloxy group having 1 to 10 carbon atoms which may have a substituent.

R²² and R²⁵ in the case where the heterocycle B is formed, and R²¹ and R²³ in the case where the heterocycle C is formed represent divalent groups —X¹—Y¹— and —X²—Y²— to which R²² and R²⁵ and R²¹ and R²³ are bonded (a side bonded to nitrogen is X¹ or X²), X¹ and X² are each a group represented by the following formula (1x) or (2x), and Y¹ and Y² are each a group represented by any of those selected from the following formulae (1y) to (5y). When X¹ and X² are each a group represented by the following formula (2x), Y¹ and Y² may each be a single bond, and in that case, may each have an oxygen atom between carbon atoms.

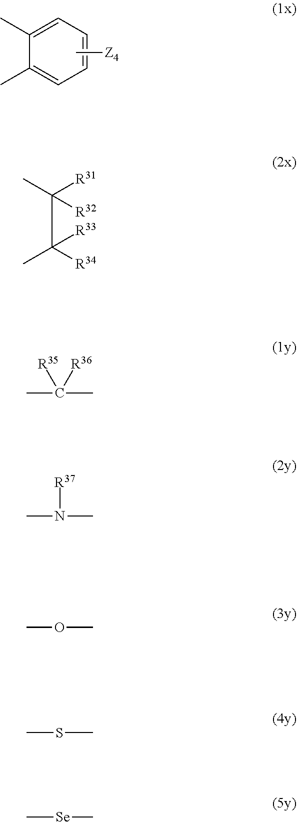

In the formula (1x), four Z's each independently represent a hydrogen atom, a hydroxy group, an alkyl group or an alkoxy group having 1 to 6 carbon atoms, or —NR³⁸R³⁹ (R³⁸ and R³⁹ each independently represent a hydrogen atom or an alkyl group having 1 to 20 carbon atoms). R³¹ to R³⁶ each independently represent a hydrogen atom, an alkyl group having 1 to 6 carbon atoms, or an aryl group having 6 to 10 carbon atoms, and R³⁷ represents an alkyl group having 1 to 6 carbon atoms or an aryl group having 6 to 10 carbon atoms.

R²¹ to R²³ and R²⁵ in the case where no heterocycle is formed, R²⁷, R²⁸, R²⁹, and R³¹ to R³⁷ may be bonded to any other among those to form a 5-membered ring or a 6-membered ring. R³¹ and R³⁶, and R³¹ and R³⁷ may be directly bonded.

R²¹, R²², R²³, and R²⁵ in the case where no heterocycle is formed each independently represent a hydrogen atom, a halogen atom, a hydroxy group, an alkyl group or an alkoxy group having 1 to 20 carbon atoms, an acyloxy group having 1 to 10 carbon atoms, an aryl group having 6 to 11 carbon atoms, or an alkaryl group having 7 to 18 carbon atoms which may have a substituent and may have an oxygen atom between carbon atoms.

Examples of the compound (I) include a compound represented by any one of formulae (I-1) to (1-3), and the compound represented by the formula (I-1) is particularly preferred from the viewpoint of a solubility in a resin, heat resistance and light resistance in a resin, and a visible light transmittance of a resin layer containing the same.

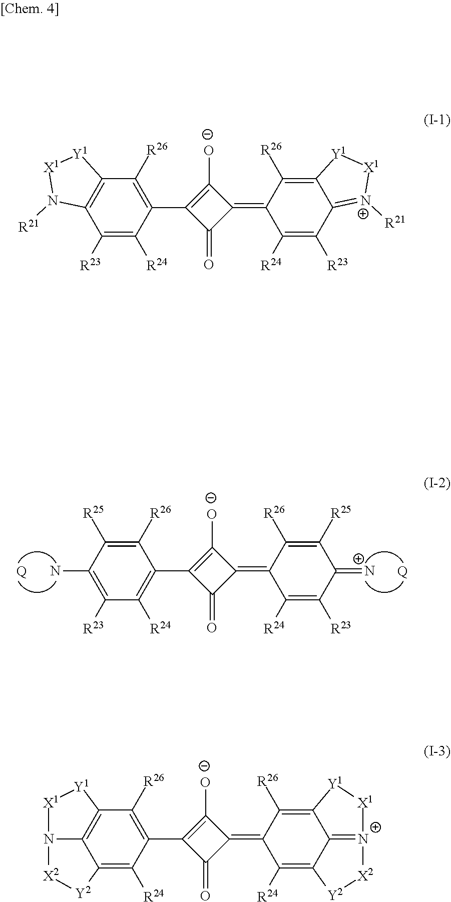

For symbols in the formulae (I-1) to (I-3), respective specifications thereof are the same as those for the same symbols in the formula (I), and preferred embodiments are also the same.

In the compound (I-1), X¹ is preferably a group (2x), and Y¹ is preferably a single bond or a group (1y). In this case, R³¹ to R³⁶ are preferably a hydrogen atom or an alkyl group having 1 to 3 carbon atoms, and more preferably a hydrogen atom or a methyl group. Specific examples of —Y¹—X¹ include divalent organic groups represented by formulae (11-1) to (12-3).

—C(CH₃)₂—CH(CH₃)— (11-1)

—C(CH₃)₂—CH₂— (11-2)

—C(CH₃)₂—CH(C₂H₅)— (11-3)

—C(CH₃)₂—C(CH₃)(nC₃H₇)— (11-4)

—C(CH₃)₂—CH₂—CH₂— (12-1)

—C(CH₃)₂—CH₂—CH(CH₃)— (12-2)

—C(CH₃)₂—CH(CH₃)—CH₂— (12-3)

In addition, in the compound (I-1), R²¹'s are independently more preferably a group represented by a formula (4-1) or (4-2), from the viewpoint of a solubility, heat resistance, and further steepness of change in the vicinity of a boundary between the visible region and the near-infrared region in the spectral transmittance curve.

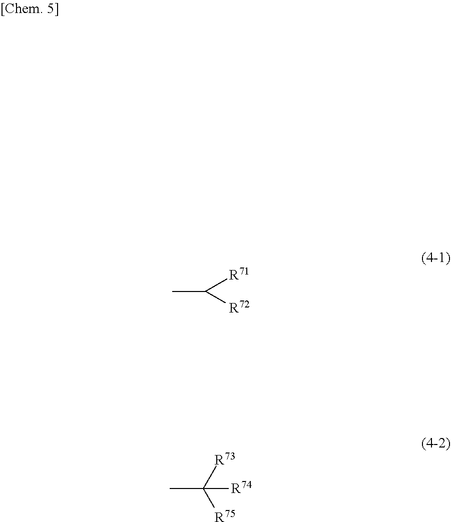

In the formulae (4-1) and (4-2), R⁷¹ to R⁷⁵ independently represent a hydrogen atom, a halogen atom, or an alkyl group having 1 to 4 carbon atoms.

In the compound (I-1), R²⁴ is preferably —NR²⁷R²⁸. As —NR²⁷R²⁸, —NH—C(═O)—R²⁹ or —NH—SO₂—R³⁰ is preferred from the viewpoint of a solubility in a resin and a coating solvent.

In the compound (I-1), a compound in which R²⁴ is —NH—C(═O)—R²⁹ is shown in a formula (I-11).

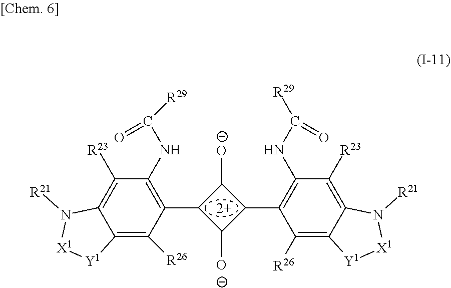

R²³ and R²⁶ are each independently preferably a hydrogen atom, a halogen atom, or an alkyl group or an alkoxy group having 1 to 6 carbon atoms, and both are more preferably a hydrogen atom.

R²⁹ is preferably an alkyl group having 1 to 20 carbon atoms which may have a substituent, an aryl group having 6 to 10 carbon atoms which may have a substituent, or an alkaryl group having 7 to 18 carbon atoms which may have a substituent and may have an oxygen atom between carbon atoms. Examples of the substituent include a hydroxy group, a carboxy group, a sulfo group, a cyano group, an alkyl group having 1 to 6 carbon atoms, a fluoroalkyl group having 1 to 6 carbon atoms, an alkoxy group having 1 to 6 carbon atoms, and an acyloxy group having 1 to 6 carbon atoms.

R²⁹ is preferably a group selected from a linear, branched, or cyclic alkyl group having 1 to 17 carbon atoms, a phenyl group which may be substituted with an alkoxy group having 1 to 6 carbon atoms, and an alkaryl group having 7 to 18 carbon atoms which may have an oxygen atom between carbon atoms.

As R²⁹, a group which is a hydrocarbon group having 5 to 25 carbon atoms and having at least one or more branches, in which one or more hydrogen atoms may be independently substituted with a hydroxy group, a carboxy group, a sulfo group, or a cyano group, and may have an unsaturated bond, an oxygen atom, or a saturated or unsaturated ring structure between carbon atoms can also be preferably used.

More specific examples of the compound (I-11) include compounds shown in the following table. In addition, in the compounds shown in the following table, meanings of respective symbols are the same on the left and right sides of a squarylium skeleton.

TABLE 1

| Dye | Substituent | | | | |
|---|---|---|---|---|---|
| abbreviation | —Y¹—X¹— | R²¹ | R²⁹ | R²³ | R²⁶ |
| (I-11-1) | —C(CH₃)₂—C(CH₃)(nC₃H₇)— | —CH₃ | —CH(C₂H₅)(nC₄H₉) | H | H |
| (I-11-2) | —C(CH₃)₂—C(CH₃)(nC₃H₇)— | —C₂H₅ | —CH(C₂H₅)(nC₄H₉) | H | H |
| (I-11-3) | —C(CH₃)₂—C(CH₃)(nC₃H₇)— | —nC₃H₇ | —CH(C₂H₅)(nC₄H₉) | H | H |
| (I-11-4) | —C(CH₃)₂—C(CH₃)(nC₃H₇)— | —CH(CH₃)₂ | —CH(C₂H₅)(nC₄H₉) | H | H |
| (I-11-5) | —C(CH₃)₂—C(CH₃)(nC₃H₇)— | —CH₃ | —nC₇H₁₅ | H | H |
| (I-11-6) | —C(CH₃)₂—C(CH₃)(nC₃H₇)— | —C₂H₅ | —nC₇H₁₅ | H | H |
| (I-11-7) | —C(CH₃)₂—C(CH₃)(nC₃H₇)— | —nC₃H₇ | —nC₇H₁₅ | H | H |
| (I-11-8) | —C(CH₃)₂—C(CH₃)(nC₃H₇)— | —CH(CH₃)₂ | —nC₇H₁₅ | H | H |
| (I-11-9) | —C(CH₃)₂—C(CH₃)(nC₃H₇)— | —CH₃ | —CH₃ | H | H |
| (I-11-10) | —C(CH₃)₂—C(CH₃)(nC₃H₇)— | —C₂H₅ | —CH₃ | H | H |
| (I-11-11) | —C(CH₃)₂—C(CH₃)(nC₃H₇)— | —nC₃H₇ | —CH₃ | H | H |
| (I-11-12) | —C(CH₃)₂—C(CH₃)(nC₃H₇)— | —CH(CH₃)₂ | —CH₃ | H | H |
| (I-11-13) | —C(CH₃)₂—C(CH₃)(nC₃H₇)— | —CH₃ | —CF₃ | H | H |
| (I-11-14) | —C(CH₃)₂—C(CH₃)(nC₃H₇)— | —C₂H₅ | —CF₃ | H | H |
| (I-11-15) | —C(CH₃)₂—C(CH₃)(nC₃H₇)— | —nC₃H₇ | —CF₃ | H | H |
| (I-11-16) | —C(CH₃)₂—C(CH₃)(nC₃H₇)— | —CH(CH₃)₂ | —CF₃ | H | H |
| (I-11-17) | —C(CH₃)₂—CH(CH₃)— | —CH₃ | —CH(C₂H₅)(nC₄H₉) | H | H |
| (I-11-18) | —C(CH₃)₂—CH(CH₃)— | —C₂H₅ | —CH(C₂H₅)(nC₄H₉) | H | H |
| (I-11-19) | —C(CH₃)₂—CH(CH₃)— | —nC₃H₇ | —CH(C₂H₅)(nC₄H₉) | H | H |
| (I-11-20) | —C(CH₃)₂—CH(CH₃)— | —CH(CH₃)₂ | —CH(C₂H₅)(nC₄H₉) | H | H |
| (I-11-21) | —C(CH₃)₂—CH(CH₃)— | —CH₃ | —nC₇H₁₅ | H | H |
| (I-11-22) | —C(CH₃)₂—CH(CH₃)— | —C₂H₅ | —nC₇H₁₅ | H | H |
| (I-11-23) | —C(CH₃)₂—CH(CH₃)— | —nC₃H₇ | —nC₇H₁₅ | H | H |
| (I-11-24) | —C(CH₃)₂—CH(CH₃)— | —CH(CH₃)₂ | —nC₇H₁₅ | H | H |
| (I-11-25) | —C(CH₃)₂—CH(CH₃)— | —CH₃ | —CH₃ | H | H |
| (I-11-26) | —C(CH₃)₂—CH(CH₃)— | —C₂H₅ | —CH₃ | H | H |
| (I-11-27) | —C(CH₃)₂—CH(CH₃)— | —nC₃H₇ | —CH₃ | H | H |
| (I-11-28) | —C(CH₃)₂—CH(CH₃)— | —CH(CH₃)₂ | —CH₃ | H | H |
| (I-11-29) | —C(CH₃)₂—CH(CH₃)— | —CH₃ | —CF₃ | H | H |
| (I-11-30) | —C(CH₃)₂—CH(CH₃)— | —C₂H₅ | —CF₃ | H | H |
| (I-11-31) | —C(CH₃)₂—CH(CH₃)— | —nC₃H₇ | —CF₃ | H | H |
| (I-11-32) | —C(CH₃)₂—CH(CH₃)— | —CH(CH₃)₂ | —CF₃ | H | H |

The compound (I-11) is, among these compounds, preferably compounds (I-11-1) to (I-11-12) and compounds (I-11-17) to (I-11-28) from the viewpoint of solubility in a resin, maximum absorption wavelength, light resistance, and heat resistance and from the viewpoint of high absorbance, and particularly preferably the compounds (I-11-1) to (I-11-12) from the viewpoint of light resistance and heat resistance. In the configuration of the present invention, since the light-shielding property of the dielectric multilayer film in an ultraviolet region is moderate, the light resistance of the dye is particularly important.

### <NIR2: Squarylium Compound>

The squarylium compound as the dye (NIR2) is preferably a compound represented by the following formula (II).

### <Squarylium Compound (II)>

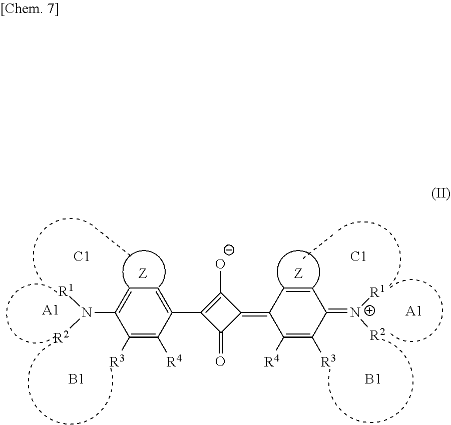

Here, symbols in the above-described formula are as follows.

Rings Z's are each independently a 5-membered ring or a 6-membered ring having 0 to 3 hetero atoms in the ring, and a hydrogen atom of the ring Z may be substituted.

Carbon atoms or hetero atoms constituting R¹ and R², R² and R³, and R¹ and the ring Z may be linked to each other to form a heterocyclic ring A1, a heterocyclic ring B1, and a heterocyclic ring C1, respectively, with nitrogen atoms, and in this case, the hydrogen atoms of the heterocyclic ring A1, the heterocyclic ring B1, and the heterocyclic ring C1 may be substituted. R¹ and R² in the case where no heterocyclic ring is formed each independently represent a hydrogen atom, a halogen atom, or a hydrocarbon group which may have an unsaturated bond, a hetero atom, a saturated or unsaturated ring structure between carbon atoms and may have a substituent. R³ in the case where no heterocyclic ring is formed and R⁴ each independently represent a hydrogen atom, a halogen atom, or an alkyl group or an alkoxy group which may have a hetero atom between carbon atoms and may have a substituent.

Examples of the compound (II) include compounds represented by any of formulae (II-1) to (II-3), and a compound represented by the formula (II-3) is particularly preferred from the viewpoint of a solubility in a resin and visible light transmissivity in a resin.

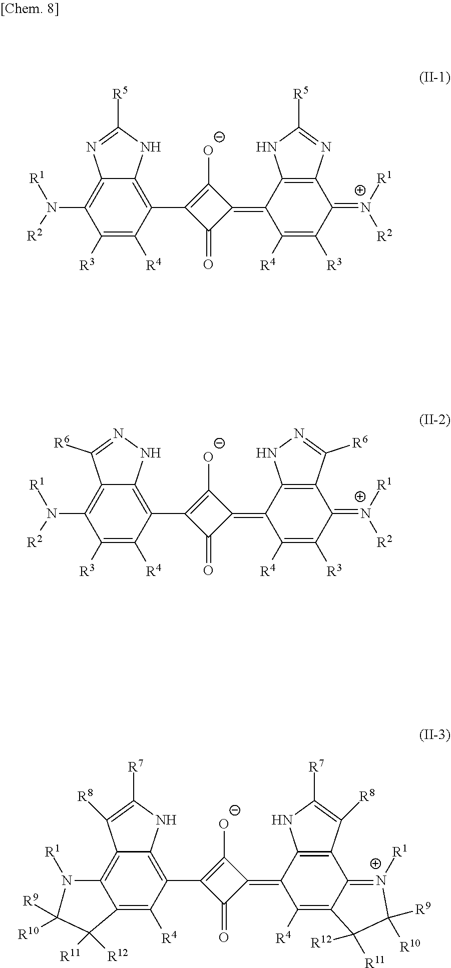

In the formulae (II-1) and (II-2), R¹ and R² each independently represent a hydrogen atom, a halogen atom, or an alkyl group having 1 to 15 carbon atoms which may have a substituent, and R³ to R⁶ each independently represent a hydrogen atom, a halogen atom, or an alkyl group having 1 to 10 carbon atoms which may have a substituent.

In the formula (II-3), R¹, R⁴, and R⁹ to R¹² each independently represent a hydrogen atom, a halogen atom, or an alkyl group having 1 to 15 carbon atoms which may have a substituent, and R⁷ and R⁸ each independently represent a hydrogen atom, a halogen atom, or an alkyl group having 1 to 5 carbon atoms which may have a substituent.

Regarding R¹ and R² in the compound (II-1) and the compound (II-2), from the viewpoint of solubility in a resin, visible light transmissivity, and the like, it is preferable that R¹ and R² are independently an alkyl group having 1 to 15 carbon atoms, it is more preferable that R¹ and R² are independently an alkyl group having 7 to 15 carbon atoms, it is further preferably at least one of R¹ and R² is an alkyl group having a branched-chain having 7 to 15 carbon atoms, and it is particularly preferable that both R¹ and R² are alkyl groups having a branched-chain and having 8 to 15 carbon atoms.

R¹ in the compound (II-3) is independently preferably an alkyl group having 1 to 15 carbon atoms, more preferably an alkyl group having 1 to 10 carbon atoms, and particularly preferably an ethyl group or an isopropyl group, from the viewpoint of solubility in a transparent resin, visible light transmissivity, and the like.

R⁴ is preferably a hydrogen atom or a halogen atom, and particularly preferably a hydrogen atom, from the viewpoint of visible light transmissivity and ease of synthesis.

R⁷ and R⁸ are independently preferably a hydrogen atom, a halogen atom, or an alkyl group having 1 to 5 carbon atoms which may be substituted with a halogen atom, and more preferably a hydrogen atom, a halogen atom, or a methyl group.

R⁹ to R¹² are each independently preferably a hydrogen atom, a halogen atom or an alkyl group having 1 to 5 carbon atoms which may be substituted with a halogen atom.

Examples of —CR⁹R¹⁰—CR¹¹R¹²— include divalent organic groups represented by the following groups (13-1) to (13-5).

—CH(CH₃)—C(CH₃)₂— (13-1)

—C(CH₃)₂—CH(CH₃)— (13-2)

—C(CH₃)₂—CH₂— (13-3)

—C(CH₃)₂—CH(C₂H₅)— (13-4)

—CH(CH₃)—C(CH₃)(CH₂—CH(CH₃)₂)— (13-5)

More specific examples of the compound (II-3) include compounds shown in the following table. In addition, in the compounds shown in the following table, meanings of respective symbols are the same on the left and right sides of a squarylium skeleton.

TABLE 2

| | Substituent | | | | | | | |
|---|---|---|---|---|---|---|---|---|
| Dye abbreviation | R¹ | R⁴ | R⁷ | R⁸ | R⁹ | R¹⁰ | R¹¹ | R¹² |
| (II-3-1) | —CH₃ | H | H | H | —CH₃ | H | —CH₃ | —CH₂—C(CH₃)₂ |
| (II-3-2) | —C₂H₅ | H | H | H | —CH₃ | H | —CH₃ | —CH₂—C(CH₃)₂ |
| (II-3-3) | —nC₃H₇ | H | H | H | —CH₃ | H | —CH₃ | —CH₂—C(CH₃)₂ |
| (II-3-4) | —CH(CH₃)₂ | H | H | H | —CH₃ | H | —CH₃ | —CH₂—C(CH₃)₂ |
| (II-3-5) | —CH₃ | H | H | H | —CH₃ | H | —CH₃ | —CH₃ |
| (II-3-6) | —C₂H₅ | H | H | H | —CH₃ | H | —CH₃ | —CH₃ |
| (II-3-7) | —nC₃H₇ | H | H | H | —CH₃ | H | —CH₃ | —CH₃ |
| (II-3-8) | —CH(CH₃)₂ | H | H | H | —CH₃ | H | —CH₃ | —CH₃ |
| (II-3-9) | —CH₃ | H | H | H | —CH₃ | H | —CH₃ | —C₂H₅ |
| (II-3-10) | —C₂H₅ | H | H | H | —CH₃ | H | —CH₃ | —C₂H₅ |
| (II-3-11) | —nC₃H₇ | H | H | H | —CH₃ | H | —CH₃ | —C₂H₅ |
| (II-3-12) | —CH(CH₃)₂ | H | H | H | —CH₃ | H | —CH₃ | —C₂H₅ |
| (II-3-13) | —CH₃ | H | H | H | —CH₃ | H | —CH₃ | —nC₃H₇ |
| (II-3-14) | —C₂H₅ | H | H | H | —CH₃ | H | —CH₃ | —nC₃H₇ |
| (II-3-15) | —nC₃H₇ | H | H | H | —CH₃ | H | —CH₃ | —nC₃H₇ |
| (II-3-16) | —CH(CH₃)₂ | H | H | H | —CH₃ | H | —CH₃ | —nC₃H₇ |

Among these compounds, the compound (II-3) is preferably compounds (II-3-1) to (II-3-4) from the viewpoint of a solubility in a resin, a high absorption coefficient, light resistance, and heat resistance.

The compounds (I) and (TI) can each be produced by known methods. The compound (I) can be produced by methods disclosed in U.S. Pat. No. 5,543,086, U.S. Patent Application Publication No. 2014/0061505, and WO2014/088063. The compound (II) can be produced by a method disclosed in WO2017/135359.

### <NIR2: Cyanine Compound>

The cyanine compound as the dye (NIR2) is preferably a compound represented by the following formula (III) or a compound represented by the following formula (IV).

### <Cyanine Compounds (III) and (IV)>

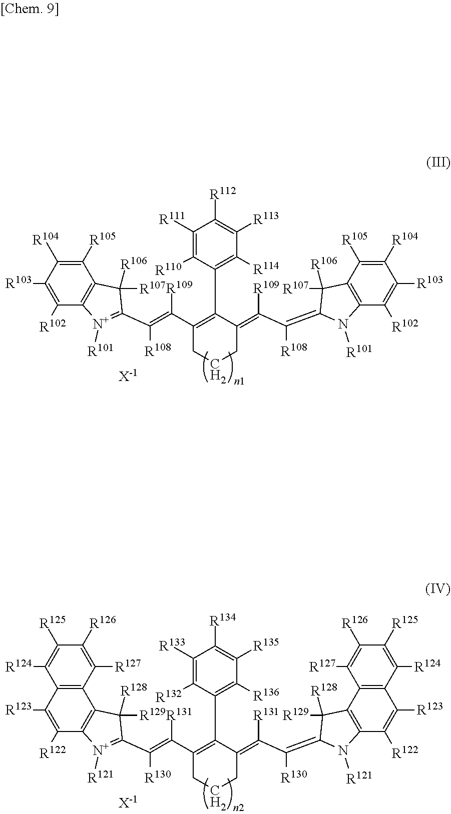

Here, symbols in the above-described formula are as follows.

R¹⁰¹ to R¹⁰⁹ and R¹²¹ to R¹³¹ each independently represent a hydrogen atom, a halogen atom, an alkyl group having 1 to 15 carbon atoms or an aryl group having 5 to 20 carbon atoms which may have a substituent. R¹¹⁰ to R¹¹4 and R¹³² to R¹³⁶ each independently represent a hydrogen atom, a halogen atom, or an alkyl group having 1 to 15 carbon atoms.

X⁻ represents a monovalent anion.

Symbols n1 and n2 are 0 or 1. A hydrogen atom bonded to a carbon ring including —(CH₂)ₙ₁— and a carbon ring including —(CH₂)ₙ₂— may be substituted with a halogen atom, an alkyl group having 1 to 15 carbon atoms or an aryl group having 5 to 20 carbon atoms which may have a substituent.

In the above description, the alkyl group (including the alkyl group of the alkoxy group) may be a linear chain, or may have a branched structure or a saturated ring structure. The aryl group refers to a group bonded via a carbon atom constituting an aromatic ring of an aromatic compound, for example, a benzene ring, a naphthalene ring, a biphenyl ring, a furan ring, a thiophene ring, and a pyrrole ring. Examples of the substituent in the alkyl group or alkoxy group having 1 to 15 carbon atoms which may have a substituent, and the aryl group having 5 to 20 carbon atoms include a halogen atom and an alkoxy group having 1 to 10 carbon atoms.

In the formula (III) and the formula (IV), R¹⁰¹ and R¹²¹ are preferably an alkyl group having 1 to 15 carbon atoms or an aryl group having 5 to 20 carbon atoms, and more preferably a branched alkyl group having 1 to 15 carbon atoms from the viewpoint of maintaining a high visible light transmittance in the resin.

In the formula (III) and the formula (IV), R¹⁰² to Rios, R¹⁰⁸, R¹⁰⁹, R¹²² to R¹²⁷, R¹³⁰, and R¹³¹ are each independently preferably a hydrogen atom, an alkyl group or an alkoxy group having 1 to 15 carbon atoms, or an aryl group having 5 to 20 carbon atoms, and more preferably a hydrogen atom from the viewpoint of obtaining a high visible light transmittance.

In the formula (III) and the formula (IV), R¹¹⁰ to R¹¹⁴ and R¹³² to R¹³⁶ are each independently preferably a hydrogen atom or an alkyl group having 1 to 15 carbon atoms, and more preferably a hydrogen atom from the viewpoint of obtaining a high visible light transmittance.

R¹⁰⁶, R¹⁰⁷, R¹²⁸, and R¹²⁹ are each independently preferably a hydrogen atom, an alkyl group having 1 to 15 carbon atoms, or an aryl group having 5 to 20 carbon atoms (which may include a chain-like, cyclic, or branched alkyl group), and more preferably a hydrogen atom, or an alkyl group having 1 to 15 carbon atoms. In addition, R¹⁰⁶ and R¹⁰⁷ are preferably the same group, and R¹²⁸ and R¹²⁹ are preferably the same group.

Examples of X⁻ include I⁻, BF₄⁻, PF₆⁻, ClO₄⁻, and anions represented by formulae (X1) and (X2), and BF₄⁻ or PF₆⁻ is preferred.

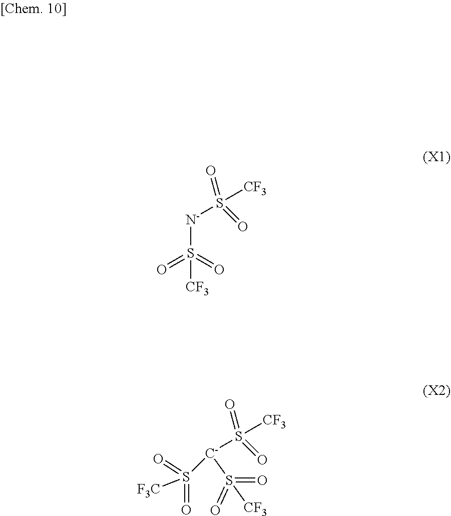 [SMILES: O=S(=O)([N-]S(=O)(=O)C(F)(F)F)C(F)(F)F ; O=S(=O)([C-](S(=O)(=O)C(F)(F)F)S(=O)(=O)C(F)(F)F)C(F)(F)F]

In the following description, a portion of the dye (III) excluding R¹⁰¹ to R¹¹⁴ is also referred to as a skeleton (III). The same applies to the dye (IV).

In the formula (III), a compound in which n1 is 1 is shown in the following formula (III-1), and a compound in which n1 is 0 is shown in the following formula (III-2).

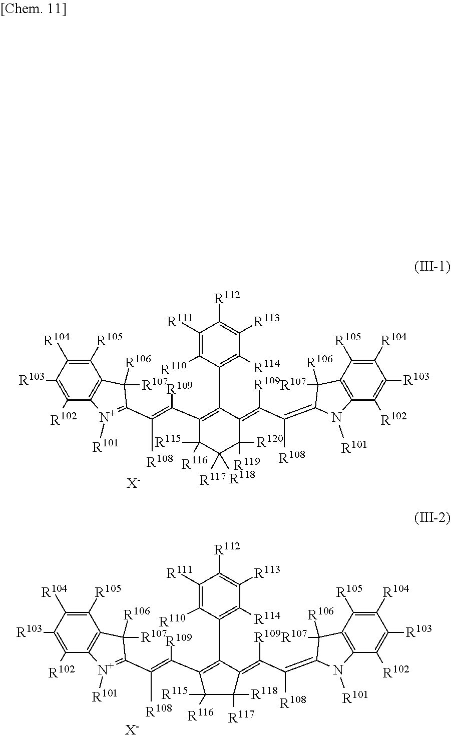

In the formula (III-1) and the formula (III-2), R¹⁰¹ to R¹¹4 and X⁻ are the same as those in the formula (III). R¹¹⁵ to R¹²⁰ each independently represents a hydrogen atom, a halogen atom, an alkyl group or an alkoxy group having 1 to 15 carbon atoms which may have a substituent, or an aryl group having 5 to 20 carbon atoms. R¹¹⁵ to R¹²⁰ are each independently preferably a hydrogen atom, an alkyl group having 1 to 15 carbon atoms, or an aryl group having 5 to 20 carbon atoms (which may include a chain-like, cyclic, or branched alkyl group), and more preferably a hydrogen atom, or an alkyl group having 1 to 15 carbon atoms. In addition, R¹¹⁵ to R¹²⁰ are preferably the same group.

In the formula (IV), a compound in which n2 is 1 is shown in the following formula (IV-1), and a compound in which n2 is 0 is shown in the following formula (IV-2).

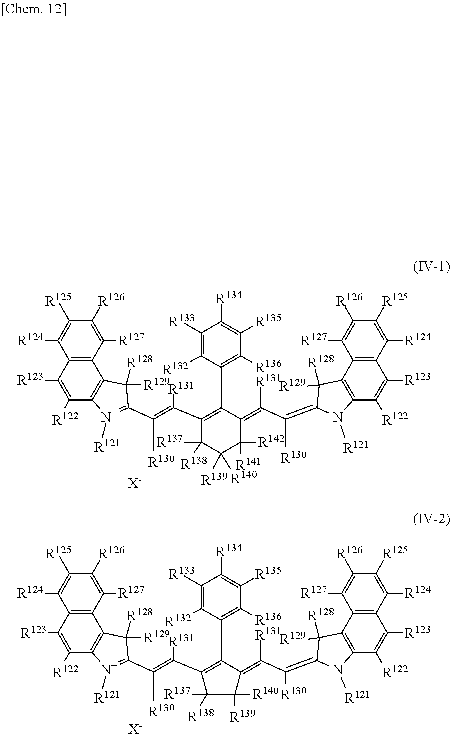

In the formula (IV-1) and the formula (IV-2), R¹²¹ to R¹³⁶ and X⁻ are the same as those in the formula (IV). R¹³⁷ to R¹⁴² each independently represent a hydrogen atom, a halogen atom, an alkyl group or an alkoxy group having 1 to 15 carbon atoms which may have a substituent, or an aryl group having 5 to 20 carbon atoms. R¹³⁷ to R¹⁴² are each independently preferably a hydrogen atom, an alkyl group having 1 to 15 carbon atoms, or an aryl group having 5 to 20 carbon atoms (which may include a chain-like, cyclic, or branched alkyl group), and more preferably a hydrogen atom, or an alkyl group having 1 to 15 carbon atoms. In addition, R¹³⁷ to R¹⁴² are preferably the same group.

More specifically, examples of the compound represented by the formula (III-1), the formula (III-2), the formula (IV-1), or the formula (IV-2) include a compound in which an atom or a group bonded to each skeleton is an atom or a group shown in the following table. In all the compounds shown in the following table, R¹⁰¹ to R¹⁰⁹ are all the same on the left and right sides of the formulae. In all the compounds shown in the following table, R¹²¹ to R¹³¹ are the same on the left and right sides of the formulae.

R¹¹⁰ to R¹¹⁴ in the following table and R¹³² to R¹³⁶ in the following table each represent an atom or a group bonded to a benzene ring at the center of each formula, and are described as “H” when all of the five are hydrogen atoms. In the case where one of R¹¹⁰ to R¹¹⁴ is a substituent and the others are hydrogen atoms, only a combination of a symbol representing the substituent and the substituent is described. For example, the description of “R¹¹²—C(CH₃)₃” indicates that R¹¹² represents —C(CH₃)₃ and the others are hydrogen atoms. The same applies to R¹³² to R¹³⁶.

R¹¹⁵ to R¹²⁰ in the following table and R¹³⁷ to R¹⁴² in the following table each represent an atom or a group bonded to a cyclohexane ring at the center of the formula (III-1) or the formula (IV-1), and are described as “H” when all the six are hydrogen atoms. In the case where one of R¹¹⁵ to R¹²⁰ is a substituent and the others are hydrogen atoms, only a combination of a symbol representing the substituent and the substituent is described. The same applies to R¹³⁷ to R¹⁴².

R¹¹⁵ to R¹¹⁸ in the following table and R¹³⁷ to R¹⁴⁰ in the following table each represent an atom or a group bonded to a cyclopentane ring at the center of the formula (III-2) or the formula (IV-2), and are described as “H” when all the four are hydrogen atoms. In the case where one of R¹¹⁵ to R¹¹⁸ is a substituent and the others are hydrogen atoms, only a combination of a symbol representing the substituent and the substituent is described. The same applies to R¹³⁷ to R¹⁴⁰.

TABLE 3

| Dye | Substituent | | | | | | | | |
|---|---|---|---|---|---|---|---|---|---|
| abbreviation | R¹⁰¹ | R¹⁰²-R¹⁰⁵ | R¹⁰⁶ | R¹⁰⁷ | R¹⁰⁸ | R¹⁰⁹ | R¹¹⁰-R¹¹⁴ | R¹¹⁵-R¹²⁰ | X⁻ |
| (III-1-1) | —CH₃ | H | —CH₃ | —CH₃ | H | H | H | H | BF₄⁻ |
| (III-1-2) | —C₂H₅ | H | —CH₃ | —CH₃ | H | H | H | H | BF₄⁻ |
| (III-1-3) | —nC₃H₇ | H | —CH₃ | —CH₃ | H | H | H | H | BF₄⁻ |
| (III-1-4) | —CH(CH₃)₂ | H | —CH₃ | —CH₃ | H | H | H | H | BF₄⁻ |
| (III-1-5) | —CH₃ | H | —CH₃ | —CH₃ | H | H | H | H | PF₆⁻ |
| (III-1-6) | —C₂H₅ | H | —CH₃ | —CH₃ | H | H | H | H | PF₆⁻ |
| (III-1-7) | —nC₃H₇ | H | —CH₃ | —CH₃ | H | H | H | H | PF₆⁻ |
| (III-1-8) | —CH(CH₃)₂ | H | —CH₃ | —CH₃ | H | H | H | H | PF₆⁻ |
| (III-1-9) | —CH₃ | H | —CH₃ | —CH₃ | H | H | H | H | N(SO₂CF₃)₂⁻ |
| (III-1-10) | —C₂H₅ | H | —CH₃ | —CH₃ | H | H | H | H | N(SO₂CF₃)₂⁻ |
| (III-1-11) | —nC₃H₇ | H | —CH₃ | —CH₃ | H | H | H | H | N(SO₂CF₃)₂⁻ |
| (III-1-12) | —CH(CH₃)₂ | H | —CH₃ | —CH₃ | H | H | H | H | N(SO₂CF₃)₂⁻ |
| (III-1-13) | —CH₃ | H | —CH₃ | —CH₃ | H | H | H | H | ClO₄⁻ |
| (III-1-14) | —C₂H₅ | H | —CH₃ | —CH₃ | H | H | H | H | ClO₄⁻ |
| (III-1-15) | —nC₃H₇ | H | —CH₃ | —CH₃ | H | H | H | H | ClO₄⁻ |
| (III-1-16) | —CH(CH₃)₂ | H | —CH₃ | —CH₃ | H | H | H | H | ClO₄⁻ |
| (III-1-17) | —CH₃ | H | H | H | H | H | H | H | BF₄⁻ |
| (III-1-18) | —C₂H₅ | H | H | H | H | H | H | H | BF₄⁻ |
| (III-1-19) | —nC₃H₇ | H | H | H | H | H | H | H | BF₁⁻ |
| (III-1-20) | —CH(CH₃)₂ | H | H | H | H | H | H | H | BF₄⁻ |
| (III-1-21) | —CH₃ | H | H | H | H | H | H | H | PF₆⁻ |
| (III-1-22) | —C₂H₅ | H | H | H | H | H | H | H | PF₆⁻ |
| (III-1-23) | —nC₃H₇ | H | H | H | H | H | H | H | PF₆⁻ |
| (III-1-24) | —CH(CH₃)₂ | H | H | H | H | H | H | H | PF₆⁻ |
| (III-1-25) | —CH₃ | H | H | H | H | H | H | H | N(SO₂CF₃)₂⁻ |
| (III-1-26) | —C₂H₅ | H | H | H | H | H | H | H | N(SO₂CF₃)₂⁻ |
| (III-1-27) | —nC₃H₇ | H | H | H | H | H | H | H | N(SO₂CF₃)₂⁻ |
| (III-1-28) | —CH(CH₃)₂ | H | H | H | H | H | H | H | N(SO₂CF₃)₂⁻ |
| (III-1-29) | —CH₃ | H | H | H | H | H | H | H | ClO₄⁻ |
| (III-1-30) | —C₂H₅ | H | H | H | H | H | H | H | ClO₄⁻ |
| (III-1-31) | —nC₃H₇ | H | H | H | H | H | H | H | ClO₄⁻ |
| (III-1-32) | —CH(CH₃)₂ | H | H | H | H | H | H | H | ClO₄⁻ |

As the dye (III-1), among these compounds, dyes (III-1-1) to (III-1-12) and the like are preferred from the viewpoint of heat resistance, light resistance, a solubility in a resin, and simplicity of synthesis.

TABLE 4

| Dye | Substituent | | | | | | | | |
|---|---|---|---|---|---|---|---|---|---|
| abbreviation | R¹⁰¹ | R¹⁰²-R¹⁰⁵ | R¹⁰⁶ | R¹⁰⁷ | R¹⁰⁸ | R¹⁰⁹ | R¹¹⁰-R¹¹⁴ | R¹¹⁵-R¹¹⁸ | X⁻ |
| (III-2-1) | —CH₃ | H | —CH₃ | —CH₃ | H | H | H | H | BF₄⁻ |
| (III-2-2) | —C₂H₅ | H | —CH₃ | —CH₃ | H | H | H | H | BF₄⁻ |
| (III-2-3) | —nC₃H₇ | H | —CH₃ | —CH₃ | H | H | H | H | BF₄⁻ |
| (III-2-4) | —CH(CH₃)₂ | H | —CH₃ | —CH₃ | H | H | H | H | BF₄⁻ |
| (III-2-5) | —CH₃ | H | —CH₃ | —CH₃ | H | H | H | H | PF₆⁻ |
| (III-2-6) | —C₂H₅ | H | —CH₃ | —CH₃ | H | H | H | H | PF₆⁻ |
| (III-2-7) | —nC₃H₇ | H | —CH₃ | —CH₃ | H | H | H | H | PF₆⁻ |
| (III-2-8) | —CH(CH₃)₂ | H | —CH₃ | —CH₃ | H | H | H | H | PF₆⁻ |
| (III-2-9) | —CH₃ | H | —CH₃ | —CH₃ | H | H | H | H | N(SO₂CF₃)₂⁻ |
| (III-2-10) | —C₂H₅ | H | —CH₃ | —CH₃ | H | H | H | H | N(SO₂CF₃)₂⁻ |
| (III-2-11) | —nC₃H₇ | H | —CH₃ | —CH₃ | H | H | H | H | N(SO₂CF₃)₂⁻ |
| (III-2-12) | —CH(CH₃)₂ | H | —CH₃ | —CH₃ | H | H | H | H | N(SO₂CF₃)₂⁻ |
| (III-2-13) | —CH₃ | H | —CH₃ | —CH₃ | H | H | H | H | ClO₄⁻ |
| (III-2-14) | —C₂H₅ | H | —CH₃ | —CH₃ | H | H | H | H | ClO₄⁻ |
| (III-2-15) | —nC₃H₇ | H | —CH₃ | —CH₃ | H | H | H | H | ClO₄⁻ |
| (III-2-16) | —CH(CH₃)₂ | H | —CH₃ | —CH₃ | H | H | H | H | ClO₄⁻ |
| (III-2-17) | —CH₃ | H | H | H | H | H | H | H | BF₄⁻ |
| (III-2-18) | —C₂H₅ | H | H | H | H | H | H | H | BF₄⁻ |
| (III-2-19) | —nC₃H₇ | H | H | H | H | H | H | H | BF₄⁻ |
| (III-2-20) | —CH(CH₃)₂ | H | H | H | H | H | H | H | BF₄⁻ |
| (III-2-21) | —CH₃ | H | H | H | H | H | H | H | PF₆⁻ |
| (III-2-22) | —C₂H₅ | H | H | H | H | H | H | H | PF₆⁻ |
| (III-2-23) | —nC₃H₇ | H | H | H | H | H | H | H | PF₆⁻ |
| (III-2-24) | —CH(CH₃)₂ | H | H | H | H | H | H | H | PF₆⁻ |
| (III-2-25) | —CH₃ | H | H | H | H | H | H | H | N(SO₂CF₃)₂⁻ |
| (III-2-26) | —C₂H₅ | H | H | H | H | H | H | H | N(SO₂CF₃)₂⁻ |
| (III-2-27) | —nC₃H₇ | H | H | H | H | H | H | H | N(SO₂CF₃)₂⁻ |
| (III-2-28) | —CH(CH₃)₂ | H | H | H | H | H | H | H | N(SO₂CF₃)₂⁻ |
| (III-2-29) | —CH₃ | H | H | H | H | H | H | H | ClO₄⁻ |
| (III-2-30) | —C₂H₅ | H | H | H | H | H | H | H | ClO₄⁻ |
| (III-2-31) | —nC₃H₇ | H | H | H | H | H | H | H | ClO₄⁻ |
| (III-2-32) | —CH(CH₃)₂ | H | H | H | H | H | H | H | ClO₄⁻ |

As the dye (III-2), among these compounds, dyes (III-2-1) to (III-2-12) and the like are preferred from the viewpoint of heat resistance, light resistance, a solubility in a resin, and simplicity of synthesis.

TABLE 5

| Dye | Substituent | | | | | | | | |
|---|---|---|---|---|---|---|---|---|---|
| abbreviation | R¹²¹ | R¹²²-R¹²⁷ | R¹²⁸ | R¹²⁹ | R¹³⁰ | R¹³¹ | R¹³²-R¹³⁶ | R¹³⁷-R¹⁴² | X⁻ |
| (IV-1-1) | —CH₃ | H | —CH₃ | —CH₃ | H | H | H | H | BF₄⁻ |
| (IV-1-2) | —CH₂CH₃ | H | —CH₃ | —CH₃ | H | H | H | H | BF₄⁻ |
| (IV-1-3) | —CH(CH₃)₂ | H | —CH₃ | —CH₃ | H | H | H | H | BF₄⁻ |
| (IV-1-4) | —nC₃H₇ | H | —CH₃ | —CH₃ | H | H | H | H | BF₄⁻ |
| (IV-1-5) | —nC₄H₉ | H | —CH₃ | —CH₃ | H | H | H | H | BF₄⁻ |
| (IV-1-6) | —CH₃ | H | —CH₃ | —CH₃ | H | H | H | H | PF₆⁻ |
| (IV-1-7) | —CH₂CH₃ | H | —CH₃ | —CH₃ | H | H | H | H | PF₆⁻ |
| (IV-1-8) | —CH(CH₃)₂ | H | —CH₃ | —CH₃ | H | H | H | H | PF₆⁻ |
| (IV-1-9) | —nC₃H₇ | H | —CH₃ | —CH₃ | H | H | H | H | PF₆⁻ |
| (IV-1-10) | —nC₄H₉ | H | —CH₃ | —CH₃ | H | H | H | H | PF₆⁻ |
| (IV-1-11) | —CH₃ | H | —CH₃ | —CH₃ | H | H | H | H | N(SO₂CF₃)₂⁻ |
| (IV-1-12) | —CH₂CH₃ | H | —CH₃ | —CH₃ | H | H | H | H | N(SO₂CF₃)₂⁻ |
| (IV-1-13) | —CH(CH₃)₂ | H | —CH₃ | —CH₃ | H | H | H | H | N(SO₂CF₃)₂⁻ |
| (IV-1-14) | —nC₃H₇ | H | —CH₃ | —CH₃ | H | H | H | H | N(SO₂CF₃)₂⁻ |
| (IV-1-15) | —nC₄H₉ | H | —CH₃ | —CH₃ | H | H | H | H | N(SO₂CF₃)₂⁻ |
| (IV-1-16) | —CH₃ | H | —CH₃ | —CH₃ | H | H | H | H | ClO₄⁻ |
| (IV-1-17) | —CH₂CH₃ | H | —CH₃ | —CH₃ | H | H | H | H | ClO₄⁻ |
| (IV-1-18) | —CH(CH₃)₂ | H | —CH₃ | —CH₃ | H | H | H | H | ClO₄⁻ |
| (IV-1-19) | —nC₃H₇ | H | —CH₃ | —CH₃ | H | H | H | H | ClO₄⁻ |
| (IV-1-20) | —nC₄H₉ | H | —CH₃ | —CH₃ | H | H | H | H | ClO₄⁻ |
| (IV-1-21) | —CH₃ | H | H | H | H | H | H | H | BF₄⁻ |
| (IV-1-22) | —CH₂CH₃ | H | H | H | H | H | H | H | BF₄⁻ |
| (IV-1-23) | —CH(CH₃)₂ | H | H | H | H | H | H | H | BF₄⁻ |
| (IV-1-24) | —nC₃H₇ | H | H | H | H | H | H | H | BF₄⁻ |
| (IV-1-25) | —nC₄H₉ | H | H | H | H | H | H | H | BF₄⁻ |
| (IV-1-26) | —CH₃ | H | H | H | H | H | H | H | PF₆⁻ |
| (IV-1-27) | —CH₂CH₃ | H | H | H | H | H | H | H | PF₆⁻ |
| (IV-1-28) | —CH(CH₃)₂ | H | H | H | H | H | H | H | PF₆⁻ |
| (IV-1-29) | —nC₃H₇ | H | H | H | H | H | H | H | PF₆⁻ |
| (IV-1-30) | —nC₄H₉ | H | H | H | H | H | H | H | PF₆⁻ |
| (IV-1-31) | —CH₃ | H | H | H | H | H | H | H | N(SO₂CF₃)₂⁻ |
| (IV-1-32) | —CH₂CH₃ | H | H | H | H | H | H | H | N(SO₂CF₃)₂⁻ |
| (IV-1-33) | —CH(CH₃)₂ | H | H | H | H | H | H | H | N(SO₂CF₃)₂⁻ |
| (IV-1-34) | —nC₃H₇ | H | H | H | H | H | H | H | N(SO₂CF₃)₂⁻ |
| (IV-1-35) | —nC₄H₉ | H | H | H | H | H | H | H | N(SO₂CF₃)₂⁻ |
| (IV-1-36) | —CH₃ | H | H | H | H | H | H | H | ClO₄⁻ |
| (IV-1-37) | —CH₂CH₃ | H | H | H | H | H | H | H | ClO₄⁻ |
| (IV-1-38) | —CH(CH₃)₂ | H | H | H | H | H | H | H | ClO₄⁻ |
| (IV-1-39) | —nC₃H₇ | H | H | H | H | H | H | H | ClO₄⁻ |
| (IV-1-40) | —nC₄H₉ | H | H | H | H | H | H | H | ClO₄⁻ |

As the dye (IV-1), among these compounds, dyes (IV-1-1) to (IV-1-12) and the like are preferred from the viewpoint of heat resistance, light resistance, a solubility in a resin, and simplicity of synthesis.

TABLE 6

| Dye | Substituent | | | | | | | | |
|---|---|---|---|---|---|---|---|---|---|
| abbreviation | R¹²¹ | R¹²²-R¹²⁷ | R¹²⁸ | R¹²⁹ | R¹³⁰ | R¹³¹ | R¹³²-R¹³⁶ | R¹³⁷-R¹⁴⁰ | X− |
| (IV-2-1) | —CH₃ | H | —CH₃ | —CH₃ | H | H | H | H | BF₄− |
| (IV-2-2) | —CH₂CH₃ | H | —CH₃ | —CH₃ | H | H | H | H | BF₄− |
| (IV-2-3) | —CH(CH₃)₂ | H | —CH₃ | —CH₃ | H | H | H | H | BF₄− |
| (IV-2-4) | —nC₃H₇ | H | —CH₃ | —CH₃ | H | H | H | H | BF₄− |
| (IV-2-5) | —nC₄H₉ | H | —CH₃ | —CH₃ | H | H | H | H | BF₄− |
| (IV-2-6) | —CH₃ | H | —CH₃ | —CH₃ | H | H | H | H | PF₆− |
| (IV-2-7) | —CH₂CH₃ | H | —CH₃ | —CH₃ | H | H | H | H | PF₆− |
| (IV-2-8) | —CH(CH₃)₂ | H | —CH₃ | —CH₃ | H | H | H | H | PF₆− |
| (IV-2-9) | —nC₃H₇ | H | —CH₃ | —CH₃ | H | H | H | H | PF₆− |
| (IV-2-10) | —nC₄H₉ | H | —CH₃ | —CH₃ | H | H | H | H | PF₆− |
| (IV-2-11) | —CH₃ | H | —CH₃ | —CH₃ | H | H | H | H | N(SO₂CF₃)₂− |
| (IV-2-12) | —CH₂CH₃ | H | —CH₃ | —CH₃ | H | H | H | H | N(SO₂CF₃)₂− |
| (IV-2-13) | —CH(CH₃)₂ | H | —CH₃ | —CH₃ | H | H | H | H | N(SO₂CF₃)₂− |
| (IV-2-14) | —nC₃H₇ | H | —CH₃ | —CH₃ | H | H | H | H | N(SO₂CF₃)₂− |
| (IV-2-15) | —nC₄H₉ | H | —CH₃ | —CH₃ | H | H | H | H | N(SO₂CF₃)₂− |
| (IV-2-16) | —CH₃ | H | —CH₃ | —CH₃ | H | H | H | H | ClO₄− |
| (IV-2-17) | —CH₂CH₃ | H | —CH₃ | —CH₃ | H | H | H | H | ClO₄− |
| (IV-2-18) | —CH(CH₃)₂ | H | —CH₃ | —CH₃ | H | H | H | H | ClO₄− |
| (IV-2-19) | —nC₃H₇ | H | —CH₃ | —CH₃ | H | H | H | H | ClO₄− |
| (IV-2-20) | —nC₄H₉ | H | —CH₃ | —CH₃ | H | H | H | H | ClO₄− |
| (IV-2-21) | —CH₃ | H | H | H | H | H | H | H | BF₄− |
| (IV-2-22) | —CH₂CH₃ | H | H | H | H | H | H | H | BF₄− |
| (IV-2-23) | —CH(CH₃)₂ | H | H | H | H | H | H | H | BF₄− |
| (IV-2-24) | —nC₃H₇ | H | H | H | H | H | H | H | BF₄− |
| (IV-2-25) | —nC₄H₉ | H | H | H | H | H | H | H | BF₄− |
| (IV-2-26) | —CH₃ | H | H | H | H | H | H | H | PF₆− |
| (IV-2-27) | —CH₂CH₃ | H | H | H | H | H | H | H | PF₆− |
| (IV-2-28) | —CH(CH₃)₂ | H | H | H | H | H | H | H | PF₆− |
| (IV-2-29) | —nC₃H₇ | H | H | H | H | H | H | H | PF₆− |
| (IV-2-30) | —nC₄H₉ | H | H | H | H | H | H | H | PF₆− |
| (IV-2-31) | —CH₃ | H | H | H | H | H | H | H | N(SO₂CF₃)₂− |
| (IV-2-32) | —CH₂CH₃ | H | H | H | H | H | H | H | N(SO₂CF₃)₂− |
| (IV-2-33) | —CH(CH₃)₂ | H | H | H | H | H | H | H | N(SO₂CF₃)₂− |
| (TV-2-34) | —nC₃H₇ | H | H | H | H | H | H | H | N(SO₂CF₃)₂− |
| (IV-2-35) | —nC₄H₉ | H | H | H | H | H | H | H | N(SO₂CF₃)₂− |
| (IV-2-36) | —CH₃ | H | H | H | H | H | H | H | ClO₄− |
| (IV-2-37) | —CH₂CH₃ | H | H | H | H | H | H | H | ClO₄− |
| (IV-2-38) | —CH(CH₃)₂ | H | H | H | H | H | H | H | ClO₄− |
| (IV-2-39) | —nC₃H₇ | H | H | H | H | H | H | H | ClO₄− |
| (IV-2-40) | —nC₄H₉ | H | H | H | H | H | H | H | ClO₄− |

As the dye (IV-2), among these compounds, dyes (IV-2-1) to (IV-2-15) and the like are preferred from the viewpoint of heat resistance, light resistance, a solubility in a resin, and simplicity of synthesis.

The dye (III) and the dye (IV) can be produced, for example, by methods described in Dyes and dyes 73(2007) 344-352 and J. Heterocyclic chem, 42,959(2005).

A content of the NIR dye in the resin film is preferably 0.1 parts by mass to 25 parts by mass, and more preferably 0.3 parts by mass to 15 parts by mass with respect to 100 parts by mass of the resin. In the case where two or more compounds are combined, the above-described content is a total content of respective compounds.

In the case where the dye (NIR1) and the dye (NIR2) are used in combination, a content of the dye (NIR1) is preferably 0.1 parts by mass to 10 parts by mass with respect to 100 parts by mass of the resin, and a content of the dye (NIR2) is preferably 0.1 parts by mass to 10 parts by mass with respect to 100 parts by mass of the resin.

The resin film may contain another near-infrared ray absorbing dye in addition to the dye (NIR1) and the dye (NIR2). Other examples of the near-infrared ray absorbing dye include a dye having a maximum absorption wavelength longer than that of the dye (NIR2) from the viewpoint of capable of shielding light in a near-infrared region in a wide range, and specific examples thereof include a cyanine compound and a diimmonium compound.

### <UV Dye>

The resin film may contain other dyes in addition to the above-described NIR dye. As the other dyes, a dye (UV) having a maximum absorption wavelength in the resin at 370 nm to 440 nm is preferred. Accordingly, light in a near-ultraviolet region can be efficiently shielded.

Examples of the dye (UV) include an oxazole dye, a merocyanine dye, a cyanine dye, a naphthalimide dye, an oxadiazole dye, an oxazine dye, an oxazolidine dye, a naphthalic acid dye, a styryl dye, an anthracene dye, a cyclic carbonyl dye, and a triazole dye. Among them, the merocyanine dye is particularly preferred. These dyes may be used alone or in combination of two or more thereof.

A content of the dye (UV) in the resin film is preferably 0.1 parts by mass to 15 parts by mass, and more preferably 1 parts by mass to 10 parts by mass with respect to 100 parts by mass of the resin. Within such a range, deterioration in resin characteristics is unlikely to occur.

### <Substrate Configuration>

The substrate in the present filter is a composite substrate in which a resin film is laid on or above at least one main surface of the near-infrared ray absorbing glass.

The resin is not limited as long as it is a transparent resin, and one or more kinds of transparent resins selected from a polyester resin, an acrylic resin, an epoxy resin, an ene-thiol resin, a polycarbonate resin, a polyether resin, a polyarylate resin, a polysulfone resin, a polyethersulfone resin, a poly(p-phenylene) resin, a polyarylene ether phosphine oxide resin, a polyamide resin, a polyimide resin, a polyamide-imide resin, a polyolefin resin, a cyclic olefin resin, a polyurethane resin, a polystyrene resin, and the like are used. These resins may be used alone, or may be used by mixing two or more kinds thereof.

From the viewpoint of spectral characteristics, a glass transition point (Tg), and adhesion of the resin film, one or more resins selected from a polyimide resin, a polycarbonate resin, a polyester resin, and an acrylic resin are preferred.

In the case where a plurality of compounds are used as the NIR dye or other dyes, those compounds may be included in the same resin film or may be included in different resin films.

The resin film can be formed by dissolving or dispersing a dye, a resin or a raw material component of the resin, and respective components blended as necessary in a solvent to prepare a coating solution, applying the coating solution to a support, drying the coating solution, and further curing the coating solution as necessary. The support in this case may be the near-infrared ray absorbing glass used for the present filter, or may be a peelable support used only when the resin film is to be formed. The solvent may be a dispersion medium capable of stably dispersing or a solvent capable of dissolving.

The coating solution may contain a surfactant in order to improve voids due to fine bubbles, depressions due to adhesion of foreign substances and the like, and repelling in a drying process. Further, for the application of the coating solution, for example, a dip coating method, a cast coating method, or a spin coating method can be used. The above-described coating solution is applied onto the support and then dried to form a resin film. In the case where the coating solution contains a raw material component of the transparent resin, a curing process such as thermal curing or photocuring is further performed.

The resin film can also be produced into a film shape by extrusion molding. The substrate can be produced by laminating the obtained film-shaped resin film on the near-infrared ray absorbing glass and integrating the resin film by thermal press fitting or the like.

The optical filter may have one layer of the resin film, or may have two or more layers of the resin film. In the case where the optical filter has two or more layers of the resin film, respective layers may have the same configuration or different configurations.

A thickness of the resin film is preferably 10 μm or less and more preferably 5 μm or less from the viewpoint of in-plane film thickness distribution and appearance quality in a substrate after coating, and is preferably 0.5 μm or more from the viewpoint of exhibiting desired spectral characteristics at an appropriate dye concentration. In the case where the optical filter has two or more layers of resin films, a total thickness of the respective resin films is preferably within the above-described range.

A shape of the substrate is not particularly limited, and may be a block shape, a plate shape, or a film shape.

The present filter may include, as another component, for example, a component (layer) that provides absorption by inorganic fine particles or the like that control transmission and absorption of light in a specific wavelength region. Specific examples of the inorganic fine particles include indium tin oxides (ITO), antimony-doped tin oxides (ATO), cesium tungstate, and lanthanum boride. The ITO fine particles and the cesium tungstate fine particles have a high transmittance for visible light and have a light absorbing property in a wide range of an infrared wavelength region exceeding 1,200 nm, and thus can be used in the case where a shielding property of infrared light is required.

From the above, the present description discloses the following optical filters and the like.

[1] An optical filter including:
a substrate;
a dielectric multilayer film (I) laid on or above one main surface of the substrate as an outermost layer; and
a dielectric multilayer film (II) laid on or above the other main surface of the substrate as an outermost layer, in which
the substrate includes a near-infrared ray absorbing glass and a resin film, the resin film being laid on or above at least one main surface of the near-infrared ray absorbing glass,
the resin film includes a resin and a dye (NIR1) having a maximum absorption wavelength at 680 nm to 870 nm in the resin, and
the optical filter satisfies all of the following spectral characteristics (i-1) to (i-8):
(i-1) an average transmittance T_{440-600(0deg)AVE} at a wavelength of 440 nm to 600 nm in a spectral transmittance curve at an incident angle of 0 degrees is 86% or more,
(i-2) an absolute value of a difference between a wavelength IR50_{(40deg)T} at which a transmittance is 50% in a wavelength range of 550 nm to 750 nm in the spectral transmittance curve at the incident angle of 0 degrees and a wavelength IR50_{(40deg)T} at which a transmittance is 50% in the wavelength range of 550 nm to 750 nm in a spectral transmittance curve at an incident angle of 40 degrees is 6 nm or less,
(i-3) an average transmittance T_{700-800(0deg)AVE} at a wavelength of 700 nm to 800 nm in the spectral transmittance curve at the incident angle of 0 degrees is 1% or less,
(i-4) an average transmittance T_{800-1200(0deg)AVE} at a wavelength of 800 nm to 1200 nm in the spectral transmittance curve at the incident angle of 0 degrees is 3% or less,
(i-5) when a side of the dielectric multilayer film (I) is set as an incident direction, an average reflectance RI_{440-600(5deg)AVE} at a wavelength of 440 nm to 600 nm in a spectral reflectance curve at an incident angle of 5 degrees is 4% or less,
(i-6) when the side of the dielectric multilayer film (I) is set as the incident direction, an average reflectance RI_{800-1200(5deg)AVE} at a wavelength of 800 nm to 1200 nm in the spectral reflectance curve at the incident angle of 5 degrees is 95% or more,
(i-7) when a side of the dielectric multilayer film (II) is set as the incident direction, an average reflectance RII_{700-800(40deg)AVE} at a wavelength of 700 nm to 800 nm in a spectral reflectance curve at an incident angle of 40 degrees is 5.5% or less, and
(i-8) when the side of the dielectric multilayer film (II) is set as the incident direction, an average reflectance RII_{800-1200(40deg)AVE} at a wavelength of 800 nm to 1200 nm in the spectral reflectance curve at the incident angle of 40 degrees is 10% or more.

[2] The optical filter according to [1], in which the optical filter further satisfies the following spectral characteristics (i-9) and (i-10):
(i-9) when the side of the dielectric multilayer film (II) is set as the incident direction, an average reflectance RII_{700-800(50deg)AVE} at a wavelength of 700 nm to 800 nm in a spectral reflectance curve at an incident angle of 50 degrees is 8% or less, and
(i-10) when the side of the dielectric multilayer film (II) is set as the incident direction, an average reflectance RII_{800-1200(50deg)AVE} at a wavelength of 800 nm to 1200 nm in the spectral reflectance curve at the incident angle of 50 degrees is 10% or more.

[3] The optical filter according to [1] or [2], in which the near-infrared ray absorbing glass satisfies all of the following spectral characteristics (iii-1) to (iii-3):
(iii-1) an average internal transmittance T_{400-600AVE} at a wavelength of 400 nm to 600 nm is 90% or more,
(iii-2) an average internal transmittance T_{700-800AVE} at a wavelength of 700 nm to 800 nm is 40% or less, and
(iii-3) an average internal transmittance T_{800-1200AVE} at a wavelength of 800 nm to 1200 nm is 40% or less.

[4] The optical filter according to any one of [1] to [3], in which the dielectric multilayer film (II) is laid on or above the resin film.

[5] The optical filter according to any one of [1] to [4], in which the dielectric multilayer film (II) satisfies all of the following spectral characteristics (v-II-1) and (v-II-2):
(v-II-1) a maximum reflectance RII_{700-800(5deg)MAX} at a wavelength of 700 nm to 800 nm in a spectral reflectance curve at an incident angle of 5 degrees is 8% or less, and
(v-II-2) an average reflectance RII_{700-800(5deg)AVE} at the wavelength of 700 nm to 800 nm in the spectral reflectance curve at the incident angle of 5 degrees is 6% or less.

[6] The optical filter according to any one of [1] to [5], in which the dielectric multilayer film (II) satisfies all of the following spectral characteristics (v-II-3) to (v-II-5):
(v-II-3) a maximum reflectance RII_{700-800(5deg)MAX} at a wavelength of 700 nm to 800 nm in a spectral reflectance curve at an incident angle of 5 degrees is 7.5% or less,
(v-II-4) an average reflectance RII_{700-800(5deg)AVE} at the wavelength of 700 nm to 800 nm in the spectral reflectance curve at the incident angle of 5 degrees is 5.5% or less, and
(v-II-5) an average reflectance RII_{800-1200(5deg)AVE} at a wavelength of 800 nm to 1200 nm in the spectral reflectance curve at the incident angle of 5 degrees is 20% or more.

[7] The optical filter according to any one of [1] to [6], in which the dielectric multilayer film (II) further satisfies the following spectral characteristic (v-II-6):
(v-II-6) an average reflectance RII_{440-600(5deg)AVE} at a wavelength of 440 nm to 600 nm in a spectral reflectance curve at an incident angle of 5 degrees is 6% or less.

[8] The optical filter according to any one of [1] to [7], in which the optical filter further satisfies the following spectral characteristic (i-12):
(i-12) an absolute value of a difference between IR50_{(0deg)T} and IR50_{(5deg)R} is 85 nm or more, where the IR50_{(0deg)T} is a wavelength at which a transmittance is 50% in a wavelength range of 550 nm to 750 nm in the spectral transmittance curve at the incident angle of 0 degrees and the IR50_{(5deg)R} is a wavelength at which a reflectance is 50% in a wavelength range of 550 nm to 750 nm in the spectral reflectance curve at the incident angle of 5 degrees when the side of the dielectric multilayer film (I) is set as the incident direction.

[9] The optical filter according to any one of [1] to [8], in which the resin film satisfies all of the following spectral characteristics (iv-1) to (iv-3):
(iv-1) an average internal transmittance T_{440-600AVE} at a wavelength of 440 nm to 600 nm is 90% or more,
(iv-2) an average internal transmittance T_{700-800AVE} at a wavelength of 700 nm to 800 nm is 50% or less, and
(iv-3) IR50_{(L)}-IR50_{(S)}≥100 nm, where the IR50_{(S)} is a shortest wavelength and the IR50_{(L)} is a longest wavelength at which an internal transmittance is 50% in a spectral transmittance curve at a wavelength of 600 nm to 800 nm.

[10] The optical filter according to any one of [1] to [9], in which the resin film further includes a dye (NIR2) having a maximum absorption wavelength at 680 nm to 870 nm in the resin, and the maximum absorption wavelength of the dye (NIR2) is different from the maximum absorption wavelength of the dye (NIR1).

[11] An imaging device including: the optical filter according to any of [1] to [10].

### EXAMPLES

Next, the present invention will be described more specifically with reference to Examples.

For measurement of each spectral characteristic, an ultraviolet-visible spectrophotometer (UH-4150 type, manufactured by Hitachi High-Tech Corporation) was used.

The spectral characteristic in the case where an incident angle is not particularly specified is a value measured at an incident angle of 0 degrees (in a direction perpendicular to a main surface of an optical filter).

Dyes used in respective Examples are as follows.

Compound NIR1 (squarylium compound): synthesized based on JP2017-110209A.

Compound NIR2 (squarylium compound): synthesized based on JP2017-110209A.

Compound NIR3 (cyanine compound): synthesized based on a method described in Dyes and Pigments, 73, 344-352 (2007).

Compound NIR4 (squarylium compound): synthesized based on WO2017/135359.

Compound NIR5 (phthalocyanine compound): synthesized based on a method described in Journal of physical chemistry, C 117(14), 7097-7106, 2013.

Compound UV1 (merocyanine compound): synthesized based on the description of German Patent No. 10109243.

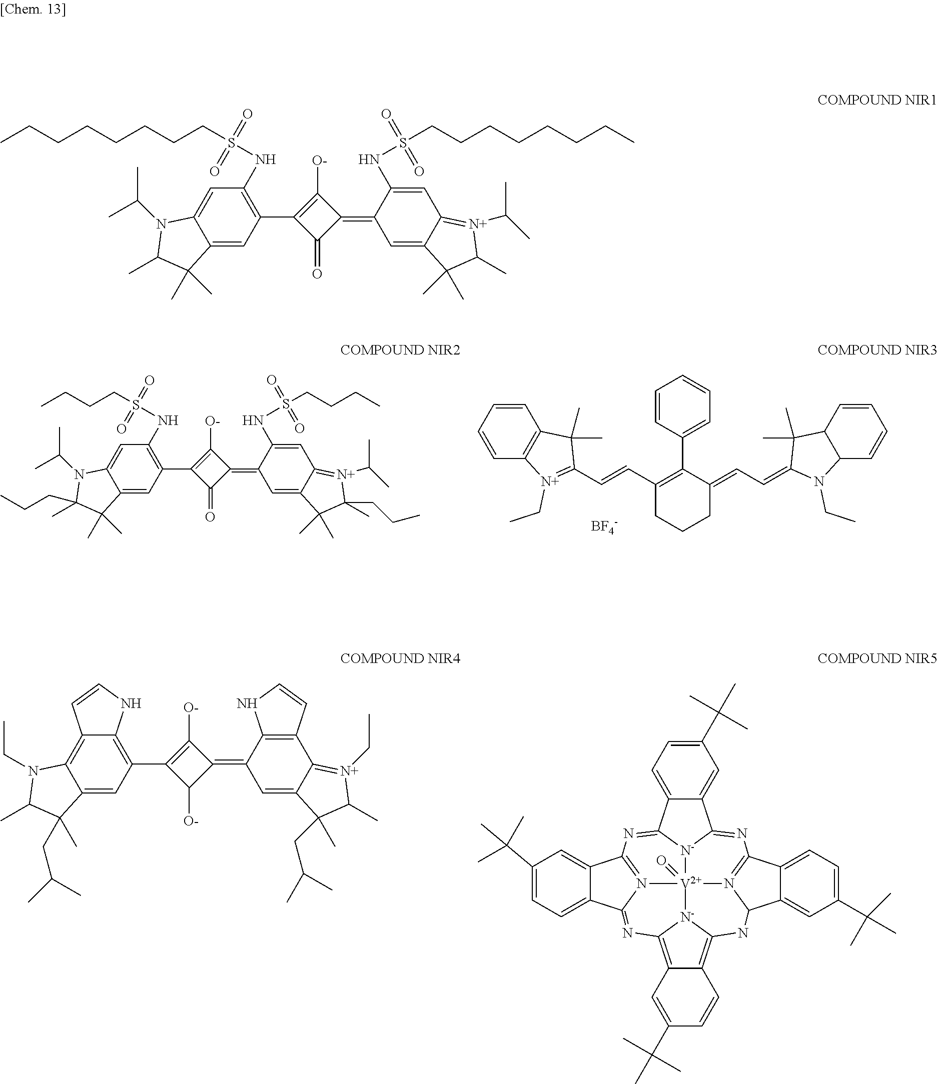

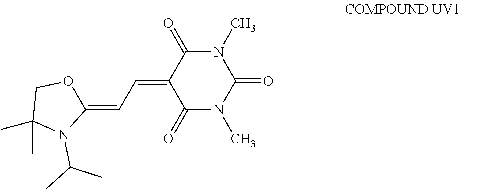 [SMILES: CC(C)N1/C(=C/C=C2C(=O)N(C)C(=O)N(C)C2=O)OCC1(C)C]

### <Spectral Characteristics of Dye in Resin>

A polyimide resin (“C3G30G” (trade name), manufactured by Mitsubishi Gas Chemical Company, Inc., refractive index: 1.59) was dissolved in a mixture of γ-butyrolactone (GBL):cyclohexanone=1:1 (mass ratio) to prepare a polyimide resin solution having a resin concentration of 8.5 mass %.

Each of the above-described dyes was added to the resin solution at a concentration of 7.5 parts by mass with respect to 100 parts by mass of the resin, followed by stirring and dissolving at 50° C. for 2 hours to obtain a coating solution. Each of the obtained coating solutions was applied to an alkaline glass (D263 glass, manufactured by SCHOTT, thickness: 0.2 mm) by a spin coating method to form coating films having a thickness of about 1.0 μm.

Transmission spectrum (incident angle of 0 degrees) and reflection spectrum (incident angle of 5 degrees) in a wavelength range of 350 nm to 1200 nm were measured for each of the obtained coating films using the spectrophotometer. A spectral internal transmittance curve was calculated using the obtained spectral transmittance curve and spectral reflectance curve.

The spectral characteristics of the above-described respective dyes in the polyimide resin are shown in the following table.

TABLE 7

| Dye number | Maximum absorption wavelength in resin |
|---|---|
| Compound NIR1 | 707 nm |
| Compound NIR2 | 712 nm |
| Compound NIR3 | 773 nm |
| Compound NIR4 | 753 nm |
| Compound NIR5 | 703 nm |
| Compound UV1 | 400 nm |

### <Spectral Characteristics of Near-Infrared Ray Absorbing Glass>

As the near-infrared ray absorbing glasses, the following fluorophosphate glasses were prepared.

Absorbing glass 1: NF50T manufactured by AGC Inc., thickness: 0.2 mm (fluorophosphate glass)

Absorbing glass 2: NF50EXA manufactured by AGC Inc., thickness: 0.2 mm (fluorophosphate glass)

Absorbing glass 3: NF50P manufactured by AGC Inc., thickness: 0.2 mm (fluorophosphate glass)

Transmission spectrum (incident angle of 0 degrees) and reflection spectrum (incident angle of 5 degrees) in a wavelength range of 350 nm to 1200 nm were measured for each of the near-infrared ray absorbing glasses using the spectrophotometer. A spectral internal transmittance curve was calculated using the obtained spectral transmittance curve and spectral reflectance curve.

The obtained spectral characteristics are shown in the following table.

TABLE 8

| | Absorbing | Absorbing | Absorbing |
|---|---|---|---|
| | glass 1 | glass 2 | glass 3 |
| Thickness | 0.2 mm | 0.2 mm | 0.2 mm |
| Average internal transmittance | 96.3 | 93.6 | 97.3 |
| T400-600AVE (%) | | | |
| Average internal transmittance | 18.7 | 8.0 | 28.2 |
| T700-800AVE (%) | | | |
| Average internal transmittance | 20.4 | 10.0 | 30.7 |
| T800-1200AVE (%) | | | |

As described above, it is understood that the used near-infrared ray absorbing glass has a high transmittance in a visible light region and is excellent in light-shielding property in a near-infrared light region.

### Example 1-1 to Example 1-4: Spectral Characteristics of Resin Film

Any of the above-described dyes were mixed with a polyimide resin solution prepared in the same manner as when calculating the spectral characteristics of each dye compound at a concentration shown in the following table, followed by stirring and dissolving at 50° C. for 2 hours to obtain a coating solution. The obtained coating solution was applied to an alkaline glass (D263 glass, manufactured by SCHOTT, thickness: 0.2 mm) by a spin coating method to form a resin film having a film thickness of 1.0 m.

Transmission spectrum (incident angle of 0 degrees) and reflection spectrum (incident angle of 5 degrees) in a wavelength range of 350 nm to 1200 nm were measured for each of the obtained resin films using the spectrophotometer. A spectral internal transmittance curve was calculated using the obtained spectral transmittance curve and spectral reflectance curve.

The obtained spectral characteristics are shown in the following table.

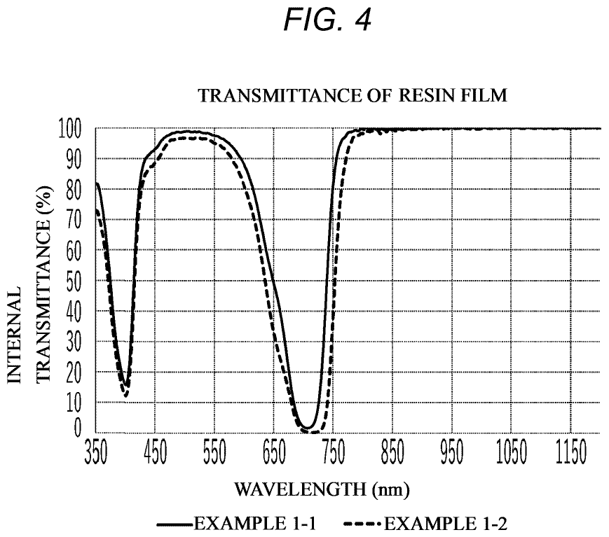

FIG. 4 illustrates spectral transmittance curves of a resin film in Example 1-1 and a resin film in Example 1-2.

### Examples 1-1 to 1-4 are Reference Examples

TABLE 9

| | | Example 1-1 | Example 1-2 | Example 1-3 | Example 1-4 |
|---|---|---|---|---|---|
| Added amount of | Compound NIR1 (λmax: 707 nm) | 7.1 | — | — | — |
| dye (mass %) | Compound NIR2 (λmax: 712 nm) | — | 5.6 | 7.1 | 7.1 |
| | Compound NIR3 (λmax: 773 nm) | — | — | 2.6 | — |
| | Compound NIR4 (λmax: 753 nm) | — | 0.9 | — | — |
| | Compound NIR5 (λmax: 703 nm) | — | — | — | 3.7 |
| | Compound UV1 (λmax: 400 nm) | 3.1 | 3.4 | 3.4 | 4.2 |
| Spectral | Average internal transmittance | 96.2 | 93.2 | 94.4 | 93.0 |
| characteristics of | T440-600AVE (%) | | | | |
| resin film | Average internal transmittance | 59.3 | 44.9 | 12.5 | 44.7 |
| | T700-800AVE (%) | | | | |
| | IR50(L) (nm) | 740 | 753 | 804 | 750 |
| | IR50(S) (nm) | 648 | 635 | 642 | 632 |
| | IR50(L) − IR50(S) (nm) | 92 | 118 | 162 | 118 |

As described above, it is understood that the obtained resin film has a high transmittance in the visible light region and is excellent in light-shielding property in the near-infrared light region of 700 nm to 800 nm. Further, it is understood that in the resin films in Example 1-2 to Example 1-4, a difference between IR_{50(L)} and IR_{50(S)} exceeds 100 nm, and light in a near-infrared light region of 700 to 800 nm were widely absorbed.

### Example 2-1: Spectral Characteristics of Dielectric Multilayer Film (I)

TiO₂ and SiO₂ were alternately laid on a surface of an alkaline Glass (D263 glass, manufactured by SCHOTT, thickness: 0.2 mm) by vapor deposition under conditions shown in the table below to form the dielectric multilayer film (I).

A spectral reflectance curve of the obtained dielectric multilayer film was measured in a wavelength range of 350 nm to 1200 nm using an ultraviolet-visible spectrophotometer.

The obtained spectral characteristics are shown in the following table.

### Example 2-1 is a Reference Example

TABLE 10

| | Example 2-1 | | |
|---|---|---|---|
| Configuration of dielectric | SiO₂ | Number of laid layers | 20 |
| multilayer film (I) | TiO₂ | Number of laid layers | 20 |
| | SiO₂ | Thickness (μm) | 3.1 |
| | TiO₂ | Thickness (μm) | 1.8 |
| | Total thickness (μm) | | 4.9 |
| Spectral characteristics of | 5 deg | Average reflectance RI440-600(5deg)AVE (%) | 5.2 |
| dielectric multilayer film | | Average reflectance RI800-1200(5deg)AVE (%) | 98.7 |
| (I) | | IR50 (nm) | 704 |
| | 40 deg | Average reflectance RI440-600(40deg)AVE (%) | 5.2 |
| | | Average reflectance RI800-1200(40deg)AVE (%) | 98.7 |
| | | IR50 (nm) | 664 |
| | 50 deg | Average reflectance RI440-600(50deg)AVE (%) | 5.2 |
| | | Average reflectance RI800-1200(50deg)AVE (%) | 98.7 |
| | | IR50 (nm) | 645 |

### Examples 3-1 to 3-4: Spectral Characteristics of Dielectric Multilayer Film (II)

TiO₂ and SiO₂ were alternately laid on a surface of an alkaline Glass (D263 glass, manufactured by SCHOTT, thickness: 0.2 mm) by vapor deposition under the conditions shown in the table below to form the dielectric multilayer film (II).

A spectral reflectance curve of the obtained dielectric multilayer film was measured in a wavelength range of 350 nm to 1200 nm using an ultraviolet-visible spectrophotometer.

The obtained spectral characteristics are shown in the following table.

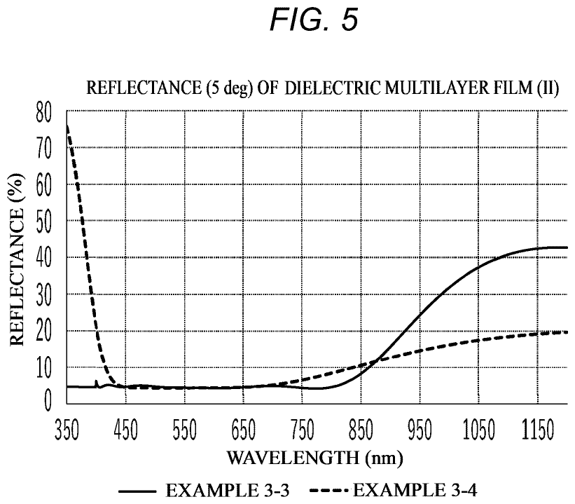

FIG. 5 illustrates spectral reflectance curves of the dielectric multilayer film (II) in Example 3-3 and the dielectric multilayer film (II) in Example 3-4.

Examples 3-1 to 3-4 are Reference Examples.

TABLE 11

| | | | Example 3-1 | Example 3-2 | Example 3-3 | Example 3-4 |
|---|---|---|---|---|---|---|
| Configuration | SiO₂ | Number of laid layers | 10 L | 13 L | 6 L | 4 L |
| of dielectric | TiO₂ | Number of laid layers | 10 L | 13 L | 5 L | 3 L |
| multilayer film | SiO₂ | Thickness (μm) | 1.6 | 1.8 | 0.5 | 0.3 |
| (II) | TiO₂ | Thickness (μm) | 2.6 | 2.8 | 0.7 | 0.4 |

| | | | | | |
|---|---|---|---|---|---|
| | Total thickness (μm) | 2.6 | 2.8 | 0.7 | 0.4 |
| Spectral | Average reflectance RH440-600(5 deg)AVE (%) | 6.2 | 4.6 | 4.7 | 4.4 |
| characteristics | Maximum reflectance RH700-800(5 deg)MAX (%) | 18.5 | 100.0 | 5.0 | 8.4 |
| of dielectric | Average reflectance RH700-800(5 deg)AVE (%) | 6.9 | 89.8 | 4.6 | 6.7 |
| multilayer film | Average reflectance RH800-1200(5 deg)AVE (%) | 79.2 | 66.5 | 28.0 | 15.4 |
| (II) | | | | | |

As described above, in Example 3-3 and Example 3-4, dielectric multilayer films having a low reflectance at 700 nm to 800 nm were obtained.

### Example 4-1 to Example 4-8: Spectral Characteristics of Optical Filter

On one of main surfaces of a substrate, the dielectric multilayer film (I) (reflection film) was formed by vapor deposition in the same manner as in Example 2-1. In only Example 4-6, the dielectric multilayer film (I) was formed in the same manner as in Example 3-1. On the other surface of the substrate, a resin film was formed in the same manner as in any one of Example 1-1 to Example 1-4. Further, the dielectric multilayer film (II) (antireflection film) was formed on the resin film by deposition in the same manner as in any one of Example 3-1 to Example 3-4 to prepare an optical filter. With respect to the obtained optical film, spectral transmittance curves at incident angles of 0 degrees and 40 degrees in a wavelength range of 350 nm to 1200 nm, a spectral reflectance curve at an incident angle of 5 degrees when an incident direction is a side of the dielectric multilayer film (I), and spectral reflectance curves at an incident angle of 5 degrees, an incident angle of 40 degrees, and an incident angle of 50 degrees when the incident direction is a side of the dielectric multilayer film (II) were measured using an ultraviolet-visible spectrophotometer.

As the substrate, any one of the above-described absorbing glasses 1 to 3, a transparent alkaline glass (D263 glass, manufactured by SCHOTT, thickness: 0.2 mm), and a transparent resin film (polycarbonate film, manufactured by Teijin Limited, PUREACE, thickness: 80 μm) was used.

Respective characteristics shown in the following table were calculated based on the obtained data of the spectral characteristics.

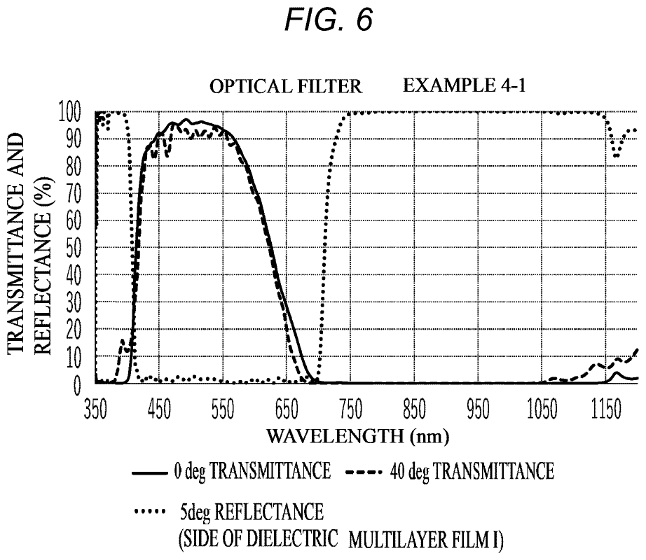

FIG. 6 illustrates spectral transmittance curves of the optical filter in Example 4-1 at the incident angles of 0 degrees and 40 degrees and a spectral reflectance curve at the incident angle of 5 degrees with an incident direction on a side of the dielectric multilayer film (I).

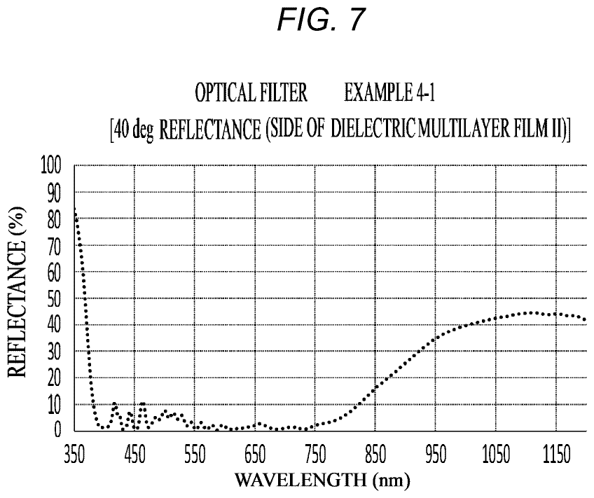

FIG. 7 illustrates a spectral reflectance curve of the optical filter in Example 4-1 at the incident angle of 40 degrees with the incident direction on the side of the dielectric multilayer film (II).

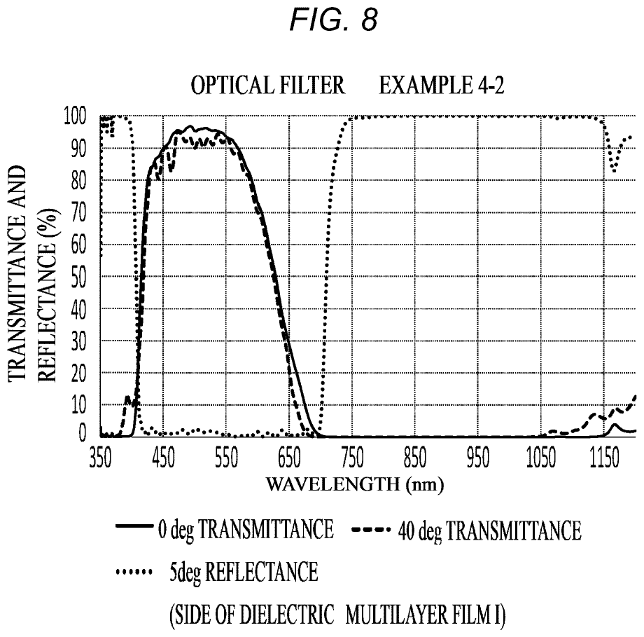

FIG. 8 illustrates spectral transmittance curves of the optical filter in Example 4-2 at the incident angles of 0 degrees and 40 degrees and a spectral reflectance curve at the incident angle of 5 degrees with an incident direction on a side of the dielectric multilayer film (I).

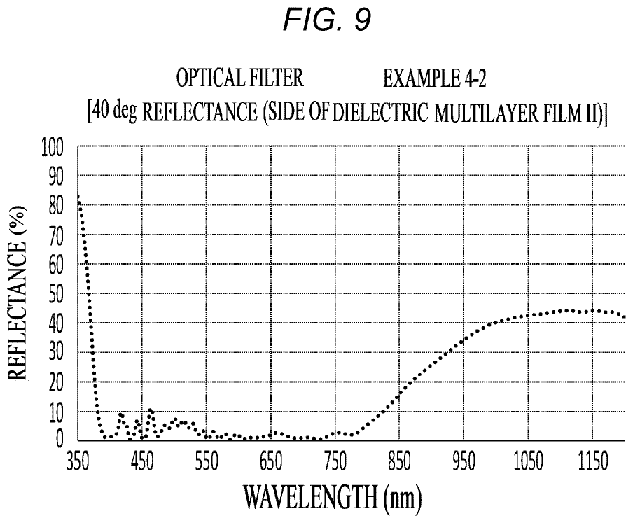

FIG. 9 illustrates a spectral reflectance curve of the optical filter in Example 4-2 at the incident angle of 40 degrees with the incident direction on the side of the dielectric multilayer film (II).

Example 4-1 to Example 4-5 are Inventive Examples, and Examples 4-6 to 4-8 are Comparative Examples.

TABLE 12

| | | | Example | Example | Example | Example |
|---|---|---|---|---|---|---|
| Optical filter | | | 4-1 | 4-2 | 4-3 | 4-4 |
| Configuration | Dielectric multilayer film II | | Example | Example | Example | Example |
| of optical | | | 3-3 | 3-3 | 3-3 | 3-3 |
| filter | Resin film | | Example | Example | Example | Example |
| | | | 1-1 | 1-2 | 1-2 | 1-3 |
| | Substrate | | Absorbing | Absorbing | Absorbing | Absorbing |
| | | | glass 1 | glass 1 | glass 3 | glass 1 |
| | Dielectric multilayer film I | | Example | Example | Example | Example |
| | | | 2-1 | 2-1 | 2-1 | 2-1 |
| Optical filter | 0 deg | Average transmittance T440- | 91.8 | 91.7 | 92.7 | 90.2 |
| spectral | transmittance | 600(0 deg)AVE (%) | | | | |
| characteristics | | Average transmittance T700- | 0.2 | 0.1 | 0.11 | 0.04 |
| | | 800(0 deg)AVE (%) | | | | |
| | | Average transmittance T800- | 0.3 | 0.3 | 0.4 | 0.3 |
| | | 1200(0 deg)AVE (%) | | | | |
| | | IR50(0 deg)T (nm) | 627 | 629 | 633 | 623 |
| | 40 deg | Average transmittance T440- | 88.5 | 88.5 | 89.5 | 86.9 |
| | transmittance | 600(40 deg)AVE (%) | | | | |
| | | Average transmittance T800- | 1.8 | 1.8 | 2.6 | 1.8 |
| | | 1200(40 deg )AVE (%) | | | | |
| | | IR50(40 deg)T (nm) | 623.3 | 625.1 | 629.4 | 620.2 |
| | Difference (nm) between IR50(0 deg)T and IR50(40 deg)T | | 3 | 3 | 4 | 3 |
| | 5 deg reflectance | Average reflectance RI440- | 1.2 | 1.2 | 1.2 | 1.2 |
| | (side of dielectric | 600(5 deg)AVE (%) | | | | |
| | multilayer film I) | Average reflectance RI800- | 98.7 | 98.7 | 98.7 | 98.7 |
| | | 1200(5 deg)AVE (%) | | | | |
| | | IR50(5 deg)R (nm) | 711 | 711 | 711 | 711 |
| | Difference (nm) between IR50(0 deg)T and IR50(5 deg)R | | 84 | 82 | 78 | 87 |
| | 5 deg reflectance | Average reflectance RH700- | 1.5 | 1.1 | 2.1 | 0.7 |
| | (side of dielectric | 800(5 deg)AVE (%) | | | | |
| | multilayer film II) | Average reflectance RH800- | 28.0 | 28.0 | 30.9 | 27.9 |
| | | 1200(5 deg)AVE (%) | | | | |
| | 40 deg reflectance | Average reflectance RH700- | 2.4 | 2.1 | 2.7 | 1.1 |
| | (side of dielectric | 800(40 deg)AVE (%) | | | | |
| | multilayer film II) | Average reflectance RH800- | 33.8 | 33.8 | 35.6 | 33.7 |
| | | 1200(40 deg)AVE (%) | | | | |
| | 50 deg reflectance | Average reflectance RH700- | 4.5 | 3.2 | 3.7 | 3.0 |
| | (side of dielectric | 800(50 deg)AVE (%) | | | | |
| | multilayer film II) | Average reflectance RH800- | 36.0 | 36.1 | 37.4 | 36.0 |
| | | 1200(50 deg)AVE (%) | | | | |

| | | | Example | Example | Example | Example |
|---|---|---|---|---|---|---|
| Optical filter | | | 4-5 | 4-6 | 4-7 | 4-8 |
| Configuration | Dielectric multilayer film II | | Example | Example | Example | Example |
| of optical filter | | | 3-3 | 3-2 | 3-4 | 3-4 |
| | Resin film | | Example | Example | Example | Example |
| | | | 1-4 | 1-1 | 1-1 | 1-1 |
| | Substrate | | Absorbing | Resin film | Transparent | Absorbing |
| | | | glass 1 | | glass | glass 1 |
| | Dielectric multilayer film I | | Example | Example | Example | Example |
| | | | 2-1 | 3-1 | 2-1 | 2-1 |
| Optical filter | 0 deg | Average transmittance T440- | 89.0 | 94.0 | 95.5 | 92.0 |
| spectral | transmittance | 600(0 deg)AVE (%) | | | | |
| characteristics | | Average transmittance T700- | 0.07 | 0.3 | 0.8 | 0.2 |
| | | 800(0 deg)AVE (%) | | | | |
| | | Average transmittance T800- | 0.3 | 0.3 | 1.3 | 0.4 |
| | | 1200(0 deg)AVE (%) | | | | |
| | | IR50(0 deg)T (nm) | 623 | 651 | 651 | 626 |
| | 40 deg | Average transmittance T440- | 85.6 | 93.8 | 91.8 | 88.3 |
| | transmittance | 600(40 deg)AVE (%) | | | | |
| | | Average transmittance T800- | 1.8 | 6.7 | 8.1 | 2.4 |
| | | 1200(40 deg )AVE (%) | | | | |
| | | IR50(40 deg)T (nm) | 620.2 | 644.7 | 643.6 | 623.2 |
| | Difference (nm) between IR50(0 deg)T and IR50(40 deg)T | | 3 | 6 | 7 | 3 |
| | 5 deg reflectance | Average reflectance RI440- | 1.2 | 2.5 | 1.0 | 1.0 |
| | (side of dielectric | 600(5 deg)AVE (%) | | | | |
| | multilayer film I) | Average reflectance RI800- | 98.7 | 99.5 | 98.7 | 98.7 |
| | | 1200(5 deg)AVE (%) | | | | |
| | | IR50(5 deg)R (nm) | 711 | 742 | 711 | 711 |
| | Difference (nm) between IR50(0 deg)T and IR50(5 deg)R | | 87 | 91 | 60 | 84 |
| | 5 deg reflectance | Average reflectance RH700- | 1.4 | 89.1 | 53.0 | 3.9 |
| | (side of dielectric | 800(5 deg)AVE (%) | | | | |
| | multilayer film II) | Average reflectance RH800- | 27.9 | 99.7 | 98.4 | 16.6 |
| | | 1200(5 deg)AVE (%) | | | | |
| | 40 deg reflectance | Average reflectance RH700- | 1.9 | 99.9 | 53.0 | 6.2 |
| | (side of dielectric | 800(40 deg)AVE (%) | | | | |
| | multilayer film II) | Average reflectance RH800- | 33.8 | 93.2 | 91.6 | 18.3 |
| | | 1200(40 deg)AVE (%) | | | | |
| | 50 deg reflectance | Average reflectance RH700- | 4.0 | 99.9 | 54.3 | 9.6 |
| | (side of dielectric | 800(50 deg)AVE (%) | | | | |
| | multilayer film II) | Average reflectance RH800- | 36.0 | 85.7 | 85.2 | 19.7 |
| | | 1200(50 deg)AVE (%) | | | | |

From the above results, it is understood that the optical filters in Example 4-1 to Example 4-5 are filters having a high transmissivity in a visible light region and a high shielding property in a near-infrared light region of 700 nm to 1200 nm, in which a reflectance at the incident angle of 40 degrees at 700 nm to 800 nm on the back surface, that is, on the side of the dielectric multilayer film (II) can be prevented to be low.

Further, in Example 4-4 and Example 4-5 in which an absolute value of the difference between the IR50_{(40deg)T} and the IR50_{(5deg)R} is 85 nm or more, the transmissivity at 700 nm to 800 nm can be prevented while preventing the reflection of the back surface at 700 nm to 800 nm as compared with Example 4-1 to Example 4-3. That is, it can be said that the optical filter can ensure the light-shielding property at 700 nm to 800 nm not by the reflection of the dielectric multilayer film but by the absorption of the NIR dye, and can prevent the generation of the stray light by the reflection from the back surface.

On the other hand, in the optical filters in Example 4-6 to Example 4-8, the reflectance at the incident angle of 40 degrees and 700 nm to 800 nm on the side of the dielectric multilayer film (II) cannot be prevented.

In the optical filter in Example 4-6, the dielectric multilayer film (II) satisfying specific spectral characteristics is not used.

In the optical filter in Example 4-7, a transparent glass having no infrared absorbing ability is used as a substrate.

In the optical filter in Example 4-8, the dielectric multilayer film (II) satisfying specific spectral characteristics is not used.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2022-032184) filed on Mar. 2, 2022, and the contents thereof are incorporated herein by reference.

### INDUSTRIAL APPLICABILITY

The optical filter of the present invention can prevent flare and ghosting, and has spectral characteristics excellent in transmissivity in a visible light region and shielding property in a near-infrared light region. The optical filter is useful for applications of imaging devices such as cameras and sensors for transport machines, for which high performance has been achieved in recent years.

### REFERENCE SIGNS LIST

1A, 1B: optical filter
10: substrate
11: near-infrared ray absorbing glass
12, 12A, and 12B: resin film
20I, 20II: dielectric multilayer film

What is claimed is:

1. An optical filter comprising:
a substrate;
a dielectric multilayer film (I) laid on or above one main surface of the substrate; and
a dielectric multilayer film (II) laid on or above the other main surface of the substrate,
wherein
the substrate comprises a near-infrared ray absorbing glass and a resin film,
the resin film comprises a resin and a dye (NIR1), and
the optical filter satisfies all of the following spectral characteristics (i-1), (i-4), (i-5) and (i-7):
(i-1) an average transmittance T_{440-600(0deg)AVE} at a wavelength of 440 nm to 600 nm in a spectral transmittance curve at an incident angle of 0 degrees is 86% or more,
(i-4) an average transmittance T_{800-1200(0deg)AVE} at a wavelength of 800 nm to 1200 nm in the spectral transmittance curve at the incident angle of 0 degrees is 3% or less,
(i-5) when a side of the dielectric multilayer film (I) is set as an incident direction, an average reflectance RI_{440-600(5deg)AVE} at a wavelength of 440 nm to 600 nm in a spectral reflectance curve at an incident angle of 5 degrees is 4% or less, and
(i-7) when a side of the dielectric multilayer film (II) is set as the incident direction, an average reflectance RII_{700-800(40deg)AVE} at a wavelength of 700 nm to 800 nm in a spectral reflectance curve at an incident angle of 40 degrees is 5.5% or less.

2. The optical filter according to claim 1, further satisfying the following spectral characteristic (i-2):
(i-2) an absolute value of a difference between a wavelength IR50_{(40deg)T} at which a transmittance is 50% in a wavelength range of 550 nm to 750 nm in the spectral transmittance curve at the incident angle of 0 degrees and a wavelength IR50_{(40deg)T} at which a transmittance is 50% in the wavelength range of 550 nm to 750 nm in a spectral transmittance curve at an incident angle of 40 degrees is 6 nm or less.

3. The optical filter according to claim 1, further satisfying the following spectral characteristic (i-3):
(i-3) an average transmittance T_{700-800(0deg)AVE} at a wavelength of 700 nm to 800 nm in the spectral transmittance curve at the incident angle of 0 degrees is 1% or less.

4. The optical filter according to claim 1, further satisfying the following spectral characteristic (i-6):
(i-6) when the side of the dielectric multilayer film (I) is set as the incident direction, an average reflectance RI_{800-1200(5deg)AVE} at a wavelength of 800 nm to 1200 nm in the spectral reflectance curve at the incident angle of 5 degrees is 95% or more.

5. The optical filter according to claim 1, further satisfying the following spectral characteristic (i-8):
(i-8) when the side of the dielectric multilayer film (II) is set as the incident direction, an average reflectance RII_{800-1200(40deg)AVE} at a wavelength of 800 nm to 1200 nm in the spectral reflectance curve at the incident angle of 40 degrees is 10% or more.

6. The optical filter according to claim 1, having an average transmittance T_{440-600(40deg)AVE} at a wavelength of 440 nm to 600 nm in a spectral transmittance curve at an incident angle of 40 degrees is 85.6% or more.

7. The optical filter according to claim 1, having an average transmittance T_{800-1200(40deg)AVE} at a wavelength of 800 nm to 1200 nm in a spectral transmittance curve at an incident angle of 40 degrees is 2.6% or less.

8. The optical filter according to claim 1, further satisfying the following spectral characteristics (i-9) and (i-10):
(i-9) when the side of the dielectric multilayer film (II) is set as the incident direction, an average reflectance RII_{700-800(50deg)AVE} at a wavelength of 700 nm to 800 nm in a spectral reflectance curve at an incident angle of 50 degrees is 8% or less, and
(i-10) when the side of the dielectric multilayer film (II) is set as the incident direction, an average reflectance RII_{800-1200(50deg)AVE} at a wavelength of 800 nm to 1200 nm in the spectral reflectance curve at the incident angle of 50 degrees is 10% or more.

9. The optical filter according to claim 1, wherein the near-infrared ray absorbing glass satisfies all of the following spectral characteristics (iii-1) to (iii-3):
(iii-1) an average internal transmittance T_{400-600AVE} at a wavelength of 400 nm to 600 nm is 90% or more,
(iii-2) an average internal transmittance T_{700-800AVE} at a wavelength of 700 nm to 800 nm is 40% or less, and
(iii-3) an average internal transmittance T_{800-1200AVE} at a wavelength of 800 nm to 1200 nm is 40% or less.

10. The optical filter according to claim 1, wherein the dielectric multilayer film (II) is laid on or above the resin film.

11. The optical filter according to claim 1, wherein the dielectric multilayer film (II) satisfies all of the following spectral characteristics (v-II-1) and (v-II-2):
(v-II-1) a maximum reflectance RII_{700-800(5deg)MAX} at a wavelength of 700 nm to 800 nm in a spectral reflectance curve at an incident angle of 5 degrees is 8% or less, and
(v-II-2) an average reflectance RII_{700-800(5deg)AVE} at the wavelength of 700 nm to 800 nm in the spectral reflectance curve at the incident angle of 5 degrees is 6% or less.

12. The optical filter according to claim 1, wherein the dielectric multilayer film (II) satisfies all of the following spectral characteristics (v-II-3) to (v-II-5):
(v-II-3) a maximum reflectance RII_{700-800(5deg)MAX} at a wavelength of 700 nm to 800 nm in a spectral reflectance curve at an incident angle of 5 degrees is 7.5% or less,
(v-II-4) an average reflectance RII_{700-800(5deg)AVE} at the wavelength of 700 nm to 800 nm in the spectral reflectance curve at the incident angle of 5 degrees is 5.5% or less, and
(v-II-5) an average reflectance RII_{800-1200(5deg)AVE} at a wavelength of 800 nm to 1200 nm in the spectral reflectance curve at the incident angle of 5 degrees is 20% or more.

13. The optical filter according to claim 1, wherein the dielectric multilayer film (II) further satisfies the following spectral characteristic (v-II-6):
(v-II-6) an average reflectance RII_{440-600(5deg)AVE} at a wavelength of 440 nm to 600 nm in a spectral reflectance curve at an incident angle of 5 degrees is 6% or less.

14. The optical filter according to claim 1, further satisfying the following spectral characteristic (i-12):
(i-12) an absolute value of a difference between IR50_{(0deg)T} and IR50_{(5deg)R} is 85 nm or more, where the IR50_{(40deg)T} is a wavelength at which a transmittance is 50% in a wavelength range of 550 nm to 750 nm in the spectral transmittance curve at the incident angle of 0 degrees and the IR50_{(5deg)R} is a wavelength at which a reflectance is 50% in a wavelength range of 550 nm to 750 nm in the spectral reflectance curve at the incident angle of 5 degrees when the side of the dielectric multilayer film (1) is set as the incident direction.

15. The optical filter according to claim 1, wherein the resin film satisfies all of the following spectral characteristics (iv-1) to (iv-3):
(iv-1) an average internal transmittance T_{440-600AVE} at a wavelength of 440 nm to 600 nm is 90% or more,
(iv-2) an average internal transmittance T_{700-800AVE} at a wavelength of 700 nm to 800 nm is 50% or less, and
(iv-3) IR50_{(L)}−IR50_{(S)}≥100 nm, where the IR50_{(S)} is a shortest wavelength and the IR50_{(L)} is a longest wavelength at which an internal transmittance is 50% in a spectral transmittance curve at a wavelength of 600 nm to 800 nm.

16. The optical filter according to claim 1, wherein the resin film further comprises a dye (NIR2) having a maximum absorption wavelength at 680 nm to 870 nm in the resin, and
the maximum absorption wavelength of the dye (NIR2) is different from a maximum absorption wavelength of the dye (NIR1).

17. An imaging device comprising the optical filter according to claim 1.
